(19) United States
(12) Patent Application Publication
(10) Pub. No.: US 2026/0096412 A1
(43) Pub. Date: Apr. 2, 2026

(54) SEMICONDUCTOR DEVICE INCLUDING CFET AND METHOD OF FABRICATING THE SAME

(71) Applicant: TAIWAN SEMICONDUCTOR MANUFACTURING COMPANY, LTD., Hsinchu (TW)

(72) Inventors: Chun-Yen LIN, Hsinchu (TW); Shih-Wei PENG, Hsinchu (TW); Wei-Cheng TZENG, Hsinchu (TW); Wei-Cheng LIN, Hsinchu (TW); Jiann-Tyng TZENG, Hsinchu (TW)

(21) Appl. No.: 19/037,935

(22) Filed: Jan. 27, 2025

Related U.S. Application Data
(60) Provisional application No. 63/701,267, filed on Sep. 30, 2024.

(51) Int. Cl. H01L 23/522; H01L 23/528; H10D 30/00; H10D 30/01; H10D 30/43; H10D 62/10; H10D 84/01; H10D 84/85

(52) U.S. Cl. CPC H10W 20/42; H10D 30/014; H10D 30/019; H10D 30/43; H10D 30/503; H10D 62/121; H10D 84/0186; H10D 84/851; H10W 20/427; H10W 20/43; H10W 20/435; H10W 20/498

(57) ABSTRACT

A semiconductor device includes a plurality of first gate structures arranged along a first direction and extending in a second direction, at least one first gate structure of the plurality of first gate structures corresponding to a first transistor region; a plurality of second gate structures arranged along the first direction and aligned with ones of the first gate structures in the second direction, at least one second gate structure of the plurality of second gate structures corresponding to a second transistor region; an insulating structure extending in the second direction and separating the plurality of first gate structures from the plurality of second gate structures; and a first conductive via in the insulating structure and configured to carry a signal for the first transistor region.

### PRIORITY CLAIM

This application claims the benefit of U.S. Provisional Application No. 63/701,267, filed Sep. 30, 2024, which is herein incorporated by reference in its entirety.

### BACKGROUND

As integrated circuits become more complex, the number of transistors and other devices increases and tends to increase die area. An approach to limiting die area increase is to use vertical stacking of transistors, such as in a complementary field effect transistor (CFET). However, vertical stacking brings its own challenges such as the potential for short-circuits in various layers of a device, the need to form structures with higher aspect ratios, and higher resistances associated with vertical connecting structures, e.g., vias and the like, that are used to connect the vertically-stacked transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor device according to some embodiments.

FIG. 2 is a cross-sectional view of a semiconductor device according to some embodiments.

FIG. 3 is a flowchart of a method of fabricating a semiconductor device that includes a PV-signal via structure according to some embodiments.

FIGS. 4a to 4d are plan views of intermediate structures in the formation of a semiconductor device according to the method of FIG. 3.

FIG. 5 is a layout diagram showing back-side layers of a semiconductor device layout according to some embodiments.

FIG. 6 is a flowchart of a method of designing a semiconductor device layout according to some embodiments.

FIG. 7a is a schematic diagram of an and-or-invert (AOI) circuit, and FIGS. 7b and 7c are layout diagrams of front-side and back-side layouts of a semiconductor device implementing the AOI circuit according to some embodiments.

FIG. 8 is a cross-sectional view of a semiconductor device according to some embodiments.

FIG. 9 is a layout diagram showing back-side layers of a semiconductor device layout according to some embodiments.

FIG. 10 is a flowchart of a method of fabricating a semiconductor device that includes PV-signal and PV-power via structures according to some embodiments.

FIGS. 11a to 11d are plan views of intermediate structures in the formation of a semiconductor device according to the method of FIG. 10.

FIG. 12 is a flowchart of a method of manufacturing a semiconductor device according to some embodiments.

FIG. 13 is a block diagram of an electronic design automation (EDA) system according to some embodiments.

FIG. 14 is a block diagram of an integrated circuit (IC) manufacturing system, and an IC manufacturing flow associated therewith according to some embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments relate to semiconductor devices including complementary field effect transistors (CFETs) and methods of fabricating and designing the same. According to some embodiments, a CFET circuit includes a power via structure configured to provide a power voltage to a CFET and includes a signal via structure having a construction corresponding to that of the power via and configured to provide a signal, e.g., a gate signal or source/drain signal. In some embodiments, the CFET is implemented with an in-boundary power rail, e.g., a backside power rail in a conductive layer under the CFET. In some embodiments, the signal via structure is in an insulating structure that overlaps or abuts a first cell boundary, e.g., a horizontal or row boundary, and the in-boundary power rail is spaced apart from the first cell boundary. Some embodiments avoid gate-to-via spacing requirements associated with a smaller deep via (DV) of another approach by placing a larger signal via structure at the first cell boundary, at ends of gate structures relative to a cell height direction rather than between gate structures relative to a cell width direction, thus reducing or avoiding a gate pitch or poly pitch limitation that stems from use of a deep via between gate structures of another approach. Some embodiments allow for relaxed process requirements and/or provide for reduced signal via resistance by using a signal via structure having a construction corresponding to that of a power via structure and having a relatively low aspect ratio as compared to a deep via of another approach. Some embodiments reduce the possibility of a short circuit in a backside layer by including a reserved zone in an adjacent cell or cells that is reserved for structures other than a conductive signal via and/or a backside contact structure. Some embodiments reduce the possibility of a short circuit in a backside layer by including an in-boundary power rail that increases a spacing between conductors in backside layers.

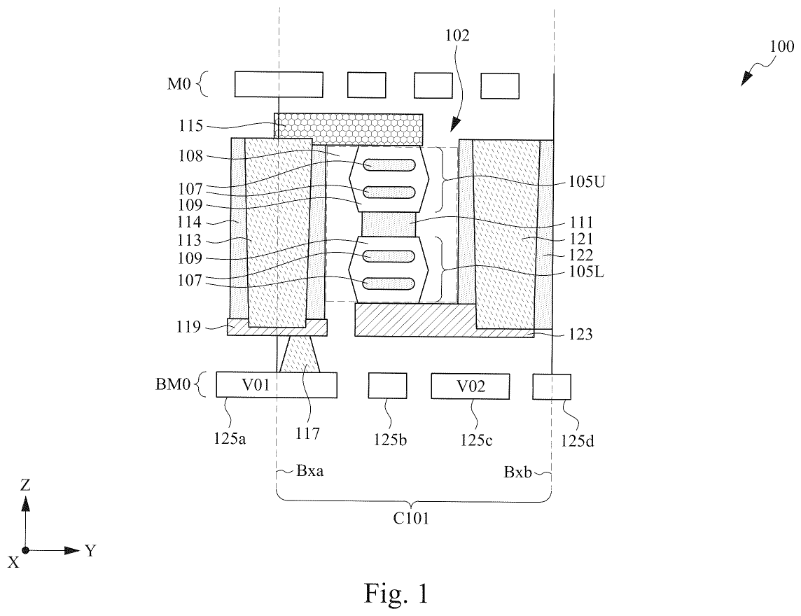

FIG. 1 is a cross-sectional view of a semiconductor device 100 according to some embodiments.

According to some embodiments, the semiconductor device 100 includes a complementary field effect transistor device 102 (CFET device, or simply CFET) that includes an upper transistor 105U and a lower transistor 105L. The CFET 102 includes an NMOS transistor and PMOS transistor in a vertical arrangement having one of the transistors stacked on the other. In some embodiments, the PMOS transistor is formed on a substrate and the NMOS transistor is formed on the PMOS transistor. However, embodiments are not limited to a particular stacking order. In some embodiments, the upper transistor 105U is the NMOS transistor and the lower transistor 105L is the PMOS transistor. In other embodiments, the upper transistor 105U is the PMOS transistor and the lower transistor 105L is the NMOS transistor. In some embodiments, forming the CFET 102 includes sequentially forming one transistor after the other, and in other embodiments forming the CFET 102 includes forming one or more features of both transistors concurrently.

Each of the upper and lower transistors 105U, 105L includes an active region 107. Merely by way of example, FIG. 1 shows two active regions 107 in each of the upper and lower transistors 105U, 105L. In some embodiments, the number of active regions 107 is one and in other embodiments is more than two. In some embodiments, the number of active regions 107 in the upper transistor 105U is different from the number of active regions 107 in the lower transistor 105L, and/or the active region(s) 107 of the upper transistor 105U have different size(s) from the active region(s) 107 of the lower transistor 105L. The active regions 107 generally extend in a first direction (denoted in FIG. 1 as being parallel to the X axis) and are crossed by a gate structure 108 (shown in FIG. 1 with dotted lines) that generally extends in a second direction (denoted in FIG. 1 as being parallel to the Y-axis). The gate structure 108 is relatively narrow in the first direction relative to a length of the gate structure 108 in the second direction.

Each of the upper and lower transistors 105U, 105L includes source/drain regions 109 (s/d regions) adjacent to the active regions 107 on either side of the gate structures. In some embodiments, the s/d regions 109 are epitaxial (EPI) structures, e.g., doped EPI structures.

The active regions 107 in the upper transistor 105U extend between ones of the s/d regions 109. In some embodiments, the active regions 107 are active regions that include nanostructures such as nanosheets or nanowires. In some embodiments, each active region 107 includes a plurality of nanostructures. In some embodiments, the nanostructures are silicon nanostructures, e.g., silicon nanosheets or the like. In some embodiments, forming the silicon nanostructures includes forming alternating layers of SiGe and Si in a vertical stack, e.g., by sequentially forming SiGe and Si layers using an epitaxial process and then selectively removing the SiGe layers, e.g., using a selective etch, such that the Si layers remain as the active regions 107.

In some embodiments, the upper transistor 105U is an NMOS transistor and the s/d regions 109 of the upper transistor 105U are n-type epitaxial (NEPI) structures. In some embodiments, the NEPI structures include one or more of AlGaAs, GaAs, GaAsP, Ge, Si, SiGe, SiP, or the like. In some embodiments, the NEPI structures are formed by epitaxial growth from the active regions 107 of the upper transistor 105U. In other embodiments, the NEPI structures are formed by epitaxial growth from another portion of the upper transistor 105U or from an intermediate or sacrificial structure. Epitaxy processes usable to form the NEPI structures include, e.g., chemical vapor deposition (CVD), ultra-high vacuum CVD (UHV-CVD), low-pressure CVD (LPCVD), plasma-enhanced CVD (PECVD), selective epitaxial growth (SEG), vapor-phase epitaxy (VPE), molecular beam epitaxy (MBE), and the like. In some embodiments, the NEPI structures are in-situ doped during the epitaxial process by introducing n-type dopants such as phosphorus or arsenic. In other embodiments, an implantation process is performed to dope the NEPI structures.

In some embodiments, the lower transistor 105L is a PMOS transistor and the s/d regions 109 of the lower transistor 105L are p-type epitaxial (PEPI) structures. In some embodiments, the PEPI structures include one or more of GeSnB, SiGeB, or the like. In some embodiments, the PEPI structures are formed by epitaxial growth from the active regions 107 of the lower transistor 105L. In other embodiments, the PEPI structures are formed by epitaxial growth from another portion of the lower transistor 105L or from an intermediate or sacrificial structure. Epitaxy processes usable to form the PEPI structures include, e.g., chemical vapor deposition (CVD), ultra-high vacuum CVD (UHV-CVD), low-pressure CVD (LPCVD), plasma-enhanced CVD (PECVD), selective epitaxial growth (SEG), vapor-phase epitaxy (VPE), molecular beam epitaxy (MBE), and the like. In some embodiments, the PEPI structures are in-situ doped during the epitaxial process by introducing p-type dopants such as boron or BF₂. In other embodiments, an implantation process is performed to dope the PEPI structures.

In FIG. 1, a common gate configuration is implemented in which the gate structure 108 fully surrounds the active region(s) 107 of the upper transistor 105U and fully surrounds the active region(s) 107 of the lower transistor 105L. The gate structure 108 is between (relative to the first direction) ones of the pairs of s/d regions 109 of the upper and lower transistors 105U, 105L. The gate structure 108 is at least partially covered by a gate isolation layer (not shown), e.g., a gate oxide layer. The gate isolation layer is between the gate structure 108 and channel regions of the active regions 107.

Relative to a third direction (denoted in FIG. 1 as being parallel to the Z-axis), the upper transistor 105U is separated from the lower transistor 105L by an isolation structure 111, which isolates the upper and lower transistors 105U, 105L from one another. In some embodiments (not shown), an isolated gate configuration is used in which the isolation structure also extends to isolate a gate structure of the upper transistor 105U from a gate structure of the lower transistor 105L. In some embodiments, the isolation structure 111 is included in a middle dielectric isolation (MDI) layer. The isolation structure 111 isolates the active structures of the upper transistor 105U from the active structures of the lower transistor 105L. In some embodiments, the isolation structure 111 includes an oxide of silicon, silicon nitride, SiOCN, or the like. In some embodiments, the isolation structure 111 is formed by, e.g., a deposition process or an oxidation process. In some embodiments, the upper transistor 105U is formed on a different substrate from a substrate on which the lower transistor 105L is formed and then the substrates are joined together, and the isolation structure 111 (or MDI layer) is an exposed layer of one of the substrates such that the isolation structure 111 is located at an interface of the substrates after the substrates are joined.

Additional structures and operations for forming the CFET 102 are described in U.S. Pat. No. 10,977,417, U.S. Patent Application Publication No. 2024/0222429 A1, and U.S. Patent Application Publication No. 2024/0341092 A1, which are incorporated herein by reference in their entireties.

At a front side of the CFET 102, a first conductive layer M0 is provided to carry power voltages and/or signals, and at a back side of the CFET 102, a first backside conductive layer BM0 is provided to carry power voltages and/or signals. Conductors in the first conductive layer M0 and the first backside conductive layer BM0 generally extend in the first direction (parallel to the X axis). In some embodiments, the conductors in the first conductive layer M0 and the first backside conductive layer BM0 extend across a plurality of cells of an integrated circuit layout.

In general, boundaries of cells (cells may also be referred to as cell regions) in semiconductor devices are discerned in a variety of ways, some examples of which follow. In some embodiments in which long axes of active regions extend in a first direction, e.g., parallel to the X-axis, a left boundary of a cell region corresponds approximately to a first imaginary line to which are aligned left-ends of active regions, and a right boundary of a cell region corresponds approximately to a second imaginary line to which are aligned right-ends of active regions. In some embodiments in which long axes of active regions extend parallel to a first direction, e.g., the X-axis, and long axes of gate segments extend parallel to a second direction perpendicular to the first direction, e.g., the Y-axis, a left boundary and/or right boundary of a cell region corresponds approximately to an instance of a gate segment which has been replaced by an isolation dummy gate. In some embodiments in which long axes of active regions and long axes of power rails extend in a first direction, e.g., the X-axis, an upper/top boundary and/or a lower/bottom boundary of a cell region corresponds approximately to an instance of a power rail.

The conductors in the first conductive layer M0 and/or the first backside conductive layer BM0 include one or more conductive materials, e.g., one or metals such as aluminum, copper, nickel, silver, tin, titanium, tungsten, or the like.

In some embodiments, the first backside conductive layer BM0 is between the CFET 102 and a substrate (not shown in FIG. 1) relative to the Z-axis direction. In other embodiments, the first backside conductive layer BM0 is on a side of the substrate opposite the CFET 102 such that the substrate is between the CFET 102 and the first backside conductive layer BM0. In some embodiments, the substrate is a semiconductor substrate, e.g., a single crystal substrate. In some embodiments, the substrate is a silicon substrate, a silicon-germanium substrate, a silicon carbide substrate, a gallium arsenide substrate, or the like. In some embodiments, the substrate includes silicon and another elemental semiconductor such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the substrate is a semiconductor-on-insulator (SOI) substrate, e.g., a silicon-on-insulator substrate. In some embodiments, the substrate includes a doped epi layer, a gradient semiconductor layer, and/or a semiconductor layer overlying another semiconductor layer of a different type, such as a silicon layer on a silicon germanium layer. In some embodiments, the substrate includes doped regions such as a p-well, an n-well, or both. In some embodiments, the substrate is a dielectric substrate, a sapphire substrate, or the like.

Although not shown in FIG. 1, conductive layers (e.g., metal layers) that are over the first conductive layer M0 are referred to as M1, M2, and the like, with M1 being between M2 and M0. Via structures (not shown) extend between the conductive layers to couple the conductive segments, where V0 is a via layer arranged between and electrically coupling the M0 layer and the M1 layer, and via layers V1, V2, and the like are used to couple upper conductive layers.

Although not shown in FIG. 1, conductive layers (e.g., metal layers) that are under the first backside conductive layer BM0 are referred to as BM1, BM2, and the like, with BM1 being between BM2 and BM0. Via structures (not shown) extend between the conductive layers to couple the conductive segments, where BV0 is a bottom via layer or backside via layer arranged between and electrically coupling the BM0 layer and the BM1 layer, and via layers BV1, BV2, and the like are used to couple lower conductive layers.

In the semiconductor device 100, a first power via (PV) structure 113 extends in the third direction (Z-axis direction) to couple a first power voltage V01 (V01 is, e.g., VSS or VDD, e.g., VSS) between the first backside conductive layer BM0 and a s/d region 109 of the upper transistor 105U. A PV structure for power (e.g., VSS or VDD) such as the first PV structure 113 may be referred to as a PV-power structure. The first power voltage V01 is coupled to a lower portion of the first PV structure 113 by way of a backside via 117 (which may be referred to as a BVDR structure and extends in the third direction from the first backside conductive layer BM0) and a first backside or lower contact 119 (which is between the backside via 117 and the lower portion of the first PV structure 113). The first lower contact 119 may be referred to as a BMD contact. In an implementation in which the first backside conductive layer BM0 is on an opposite side of the substrate relative to the CFET 102 (such that the substrate is between the CFET 102 and the first backside conductive layer BM0), the backside via 117 penetrates the substrate in some embodiments.

An upper portion of the first PV structure 113 contacts a first frontside or upper contact 115 (which may also be referred to as an MD contact), and the first upper contact 115 contacts the s/d region 109 of the upper transistor 105U. The first upper contact 115 generally extends in the second direction (parallel to the Y axis). The first PV structure 113 is at least partially surrounded by an insulating structure 114. Herein, it will be understood that references to insulating structures, insulators, or the like encompass the use of dielectric materials unless stated otherwise or otherwise apparent. In some embodiments, the insulating structure 114 is, or is included in, a gate-cutting structure that abuts the gate structures 108. In some embodiments, forming the gate structures 108 includes forming an initial gate material pattern, forming a trench in the initial gate material pattern to separate or cut gate structures in one cell from gate structures in another cell, and forming the insulating structure 114 in the trench.

A second PV structure 121 extends in the third direction to couple a signal to an s/d region 109 of the lower transistor 105L. A PV structure for a signal may be referred to as a PV-signal structure. The second PV structure 121 is surrounded by an insulating structure 122. In some embodiments, the insulating structure 122 is, or is included in, a gate-cutting structure that abuts the gate structures 108. In some embodiments, forming the gate structures 108 includes forming an initial gate material pattern, forming a trench in the initial gate material pattern to separate or cut gate structures in one cell from gate structures in another cell, and forming the insulating structure 122 in the trench. In some embodiments, the insulating structure 122 is formed as a gate-cutting structure that defines a row boundary between a first transistor region in a first cell in a first row and a second transistor region in a second cell in a second row.

In the present example embodiment, the second PV structure 121 has a structure corresponding to that of the first PV structure 113 but, whereas the first PV structure 113 is configured to couple the first power voltage V01 to the CFET 102, the second PV structure 121 is configured to couple a signal to the CFET 102. In some embodiments, the second PV structure 121 forms part of an electrical path that couples the signal from a source or drain of the lower transistor 105L to a drain or source of the upper transistor 105U (this electrical path may be referred to as diagonal signal routing in that it couples a lower source or drain region on one side of the gate structure to an upper drain or source region on an opposite side of the gate structure).

A lower portion of the second PV structure 121 contacts a second lower contact 123, and the second lower contact 123 also contacts the s/d region 109 of the lower transistor 105L. Also, although not visible in the cross-section of FIG. 1, an upper portion of the second PV structure 121 contacts a second upper contact, and the second upper contact also contacts an s/d region of the upper transistor 105U on an opposite side of the gate structure. The upper contacts are conductive structures that are formed in an MD layer (which may be referred to as a upper metal-on-diffusion layer). The upper contacts may be referred to as MD structures. The lower contacts are conductive structures that are formed in a BMD layer (which may be referred to as a lower or bottom metal-on-diffusion layer). The lower contacts may be referred to as BMD structures. The contacts are in electrical contact with s/d regions 109. The contacts include one or more conductive materials such as a metal, a metal compound, a doped semiconductor, or the like. In some embodiments, the contacts include one more metals such as Al, Co, Cu, Ru, W, or the like. In some embodiments, the contacts include one or more metal compounds such as AlCu, NiSix, TaN, TiN, TiSix, WTiN, or the like. In some embodiments, the contacts include one or more doped semiconductors such as doped Si, doped SiGe, or the like.

In some embodiments, the first PV structure 113 and the second PV structure 121 are larger (e.g., in the X and/or Y-axis directions) than a deep via (DV) used in another approach. The larger size of the PV structure (PV-power and/or PV-signal) simplifies fabrication relative to the DV of another approach due to an overall lower aspect ratio of the PV structure relative to the DV structure. Further, the larger size of the PV structure reduces resistance relative to the DV structure of another approach.

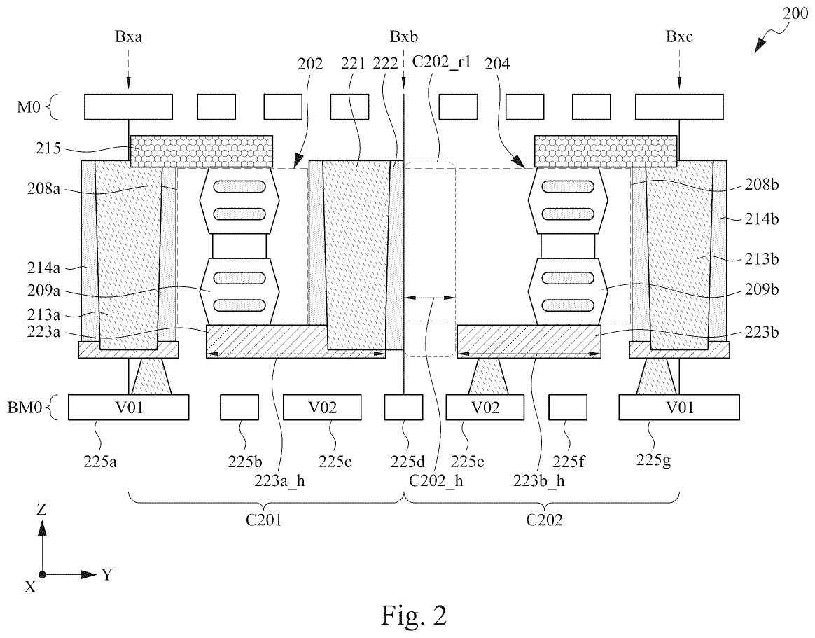

In some embodiments, the second PV structure 121 is implemented in combination with a cell design that moves a power rail inward in the cell, away from a cell boundary, which helps reduce the possibility of a short circuit between the second PV structure 121 used for a signal and a power-conveying structure in an abutting cell, relative to a structure that places all power rails on cell boundaries. A cell design in which a power rail is inward of the cell boundary may be referred to as having an in-boundary power rail. A design of a semiconductor device having abutting cells is described in connection with FIG. 2.

Description of aspects of FIG. 1 will now be made referring to a power via structure that is to convey power, PV-power, and a power via structure that is to convey a signal, PV-signal. An example of a PV-power structure is the first PV structure 113. An example of a PV-signal structure is the second PV structure 121. In some embodiments, PV-power and PV-signal structures have the same construction, materials, and/or sizes. In other embodiments, the PV-power structure has one or more of a different construction, different material(s), and or different size relative to the PV-signal structure. In some embodiments, PV-power and PV-signal structures are fabricated in simultaneous operations. In other embodiments, PV-power and PV-signal structures are fabricated using different operations and/or at different times. In some embodiments, each of PV-power and PV-signal structures have a smaller aspect ratio and/or a lower resistance than a deep via (DV) structure used in another approach.

In FIG. 1, the first power voltage V01 (e.g., one of VSS or VDD, e.g., VSS) is coupled to the CFET 102 from the first backside conductive layer BM0, and a second power voltage V02 (e.g., the other of VSS or VDD, e.g., VDD) is also coupled to the CFET 102 from the first backside conductive layer BM0. The CFET 102 is in a first cell C101 having a first horizontal cell boundary Bxa extending in the X-axis direction and a second horizontal cell boundary Bxb extending in the X-axis direction. The first horizontal cell boundary Bxa is spaced apart in the Y-axis direction from the second horizontal cell boundary Bxb. The first backside conductive layer BM0 includes conductors 125a, 125b, 125c, and 125d, each of which extends parallel to the X-axis direction and parallel to the horizontal cell boundaries Bxa, Bxb. The conductor 125a is relatively wide in the Y-axis direction as compared to the conductors 125b-125d so as to span the first horizontal cell boundary Bxa, and is configured to couple the first power voltage V01 to the first cell C101 and a second cell that abuts the first cell C101 at the first horizontal cell boundary Bxa. The conductors 125b-125d are relatively narrow in the Y-axis direction as compared to the conductor 125a. The conductor 125c is configured to couple the second power voltage V02 to the first cell C101. In FIG. 1, the conductor 125c is relatively wide in the Y-axis direction as compared to the conductors 125b and 125d. In other embodiments, the conductor 125c has the same width or a smaller width in the Y-axis direction as the conductors 125b, 125d. The conductor 125c is spaced apart in the Y-axis direction from the second horizontal cell boundary Bxb, such that the entire width of the conductor 125c is within the first cell C101 and does not abut or overlap the second horizontal cell boundary Bxb. The conductor 125c configured to supply a power voltage may be referred to as an in-boundary power rail. In FIG. 1, the second PV structure 121 (PV-signal) partially vertically overlaps the conductor 125c. In other embodiments, the conductor 125c is arranged to be spaced apart from the conductor 125c relative to the second direction so as to be free of vertical overlap with the conductor 125c.

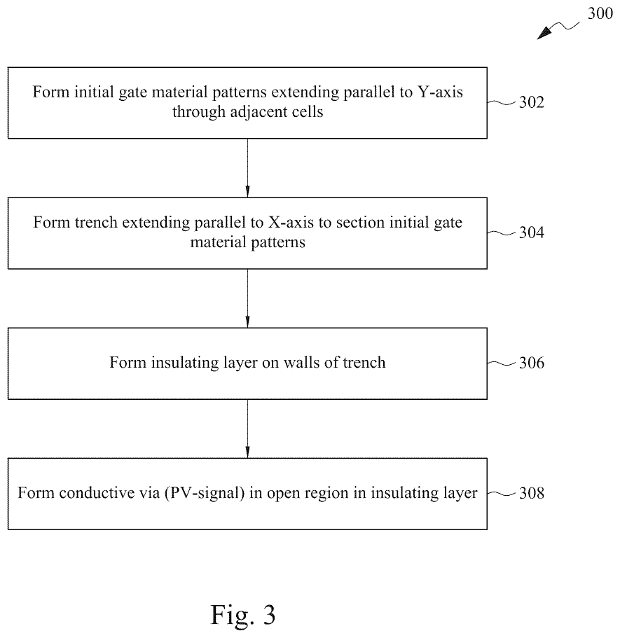

In FIG. 1, the first PV structure 113 (PV-power) is surrounded by the insulating structure 114 and the second PV structure 121 (PV-signal) is surrounded by the insulating structure 122. In some embodiments, the insulating structure 114 and the insulating structure 122 are, or are part of, respective insulating gate-cutting structures such as cut-metal-gate (CMG) structures. This will be described in further detail in connection with FIG. 3. As described in further detail below, in some embodiments forming the first PV structure 113 and/or the second PV structure 121 includes etching a trench that extends in the X-axis direction through one or more initial gate material patterns, to thus divide the initial gate material patterns into gate structures, forming or depositing an insulating layer on sides of the trench, and depositing a conductive material in an opening in the insulating layer. In an example, a cut-metal-gate (CMG) operation is modified such that a CMG trench extending in the X-axis direction has a first width in the Y-axis direction in some regions and has a second width in the Y-axis direction, greater than the first width, in other regions. The regions having the CMG trench with the second (wider) width correspond to locations of the first PV structure 113 or the second PV structure 121.

As discussed above, the semiconductor device 100 includes the PV-signal structure 121 in the insulating structure 122, which in some embodiments is, or is included in, a gate-cutting structure. The PV-signal structure 121 can be made relatively large and/or with a lower aspect ratio relative to a deep via (DV) structure of another approach, thus providing a lower-resistance signal path as compared to another approach using the DV structure. Further, since the DV structure of another approach is located between adjacent gate structures, the DV structure imposes limitations on gate pitch because of the need to maintain adequate spacing between the DV and the adjacent gate structures to avoid a DV-to-gate short circuit. In contrast, the PV-signal structure 121 can be located in a gate-cutting structure at ends of gate structures, thereby avoiding the DV limitation on gate spacing and helping to reduce a cell footprint and overall die area, and/or allowing for relaxed process requirements. For example, whereas implementing a DV between adjacent gate structures may require a gate pitch that is fifteen times or more of a gate width, the semiconductor device 100 can have gate structures 108 spaced in the first direction with a gate pitch of less than fifteen times the gate width. Further, the semiconductor device 100 includes the in-boundary backside power rail 125c, which helps to minimize the possibility of power-signal short circuit between the in-boundary power rail 125c and another conductive structure, e.g., a signal-carrying via, backside contact, or other conductor, in a cell adjacent to the second horizontal cell boundary Bxb.

FIG. 2 is a cross-sectional view of a semiconductor device 200 according to some embodiments.

The semiconductor device 200 includes a first cell C201 and a second cell C202. The first cell C201 abuts the second cell C202 in the Y-axis direction. The first cell C201 corresponds to the first cell C101 of FIG. 1 and includes a first CFET 202 corresponding to the CFET 102 of FIG. 1. The second cell C202 includes a second CFET 204.

In some embodiments, a first gate structure 208a (shown as dotted lines in FIG. 2) of the first CFET 202 and a second gate structure 208b (also shown as dotted lines) of the second CFET 204 are both formed from a same initial gate material pattern, which is sectioned into the first gate structure 208a and the second gate structure 208b by an insulating structure 222, such as a CMG structure. The gate structures 208a, 208b may be collectively referred to as gate structures 208. A PV structure 221 (PV-signal) is surrounded by the insulating structure 222. In some embodiments, the insulating structure 222 is contacted on each side in the second direction by gate structures that are cut by the insulating structure 222. In some embodiments, the PV structure 221 (PV-signal) is disposed between facing ends of the first gate structure 208a and the second gate structure 208b. The PV structure 221 (PV-signal) contacts a bottom contact 223a in a BMD layer. The bottom contact 223a also contacts an s/d region 209a of a lower transistor in the first CFET 202, so as to couple a signal (which is applied to an upper portion of the PV structure 221 (PV-signal)) to the lower transistor of the first CFET 202.

In FIG. 2, a portion of the second cell C202 is in a first region C202_r1 that is free of a via in layers corresponding to the PV structure 221 (PV-signal) of the first cell C201. In some embodiments, the first region C202_r1 has a height C202_h in the second direction that is about 0.5 times a gate pitch or contact poly pitch (CPP). In other embodiments, the height C202_h is less than 0.5 CPP. In some embodiments, the height C202_h is at least about 0.4 CPP. The first region C202_r1 may be referred to as a reserved zone. In some embodiments, the first region C202_r1 is free of a PV-signal structure and/or a bottom contact 223b, which helps to prevent a short circuit of the PV structure 221 of the first cell C201 with a via and/or the bottom contact 223b in the second cell C202 (the bottom contact 223b couples the second power voltage V02 (e.g., VDD) between the conductor 225e and an s/d region 209b of the second CFET 204). In some embodiments, avoiding having a via structure (e.g., a PV-signal structure) and/or a bottom contact in the reserved zone C202_r1 abutting with the PV structure 221 (PV-signal) of the first cell C201 helps to prevent short circuits between conductive structures in the adjacent first and second cells C201, C202. The bottom contact 223b has a height 223b_h in the second direction. The height 223b_h of the bottom contact 223b is reduced to avoid having the bottom contact 223b in the reserved zone C202_r1. In some embodiments, the height 223b_h is about twice the height C202_h of the reserved zone C202_r1. In some embodiments, the height 223b_h is about ⅔ of a height 223a_h of the bottom contact 223a.

The first cell C201 includes conductors 225a, 225b, 225c, and 225d in first backside conductive layer BM0, and the second cell C202 includes conductors 225d, 225e, 225f, and 225g in the first backside conductive layer BM0. The conductors 225a-225g generally extend parallel to the X-axis direction. The conductors 225a, 225d, and 225g are on respective first, second, and third horizontal cell boundaries Bxa, Bxb, and Bxc, with the conductor 225d being on the second horizontal cell boundary Bxb where the first cell C201 abuts the second cell C202. In some embodiments, the conductor 225d couples a signal to one or both of the first cell C201 or the second cell C202, i.e., the conductor 225d is not a power voltage conductor or power rail in some embodiments. The conductor 225a is configured to couple the first power voltage V01 (e.g., one of VSS and VDD, e.g., VSS) to PV-power structure 213a in the first cell C201. The conductor 225c is configured to couple the second power voltage V02 (e.g., the other of VSS and VDD, e.g., VDD) to the first cell C201. The conductor 225c is spaced apart in the Y-axis direction from the second horizontal cell boundary Bxb, such that the entire width of the conductor 225c is within the first cell C201 and does not abut or overlap the second horizontal cell boundary Bxb. Similarly, the conductor 225e is configured to couple the second power voltage V02 (e.g., the other of VSS and VDD, e.g., VDD) to PV-power structure 213b in the second cell C202, and is spaced apart in the Y-axis direction from the second horizontal cell boundary Bxb, such that the entire width of the conductor 225e is within the second cell C202 and does not abut or overlap the second horizontal cell boundary Bxb. In the example embodiment of FIG. 2, the conductor 225c and the conductor 225e are configured as in-boundary power rails in the first backside conductive layer BM0.

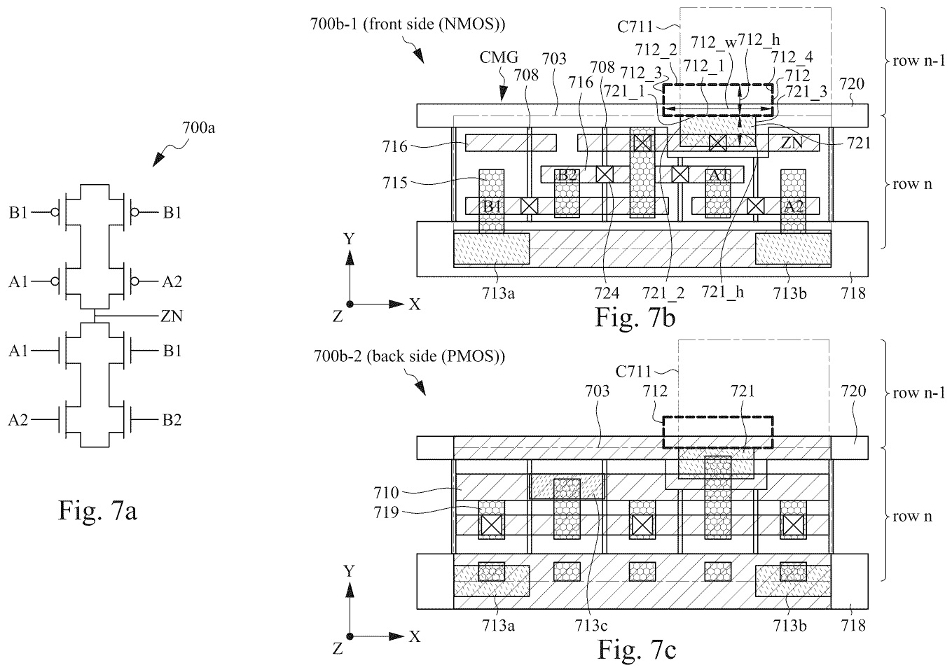

In some embodiments, the conductor 225c is vertically overlapped by and coupled to a PV-power structure to provide the second power voltage V02 (this PV-power structure is not shown in FIG. 2 but rather is offset in the first direction from the PV structure 221 (PV-signal) of the first cell C201; an example of such a PV-power structure is PV-power structure 713c in FIG. 7). Similarly, in some embodiments, the conductor 225e is vertically overlapped by and coupled to a PV-power structure in the second cell C202 to provide the second power voltage V02 to the second cell C202 (not shown in FIG. 2). In some embodiments, a PV-power structure that is in the second cell C202 and on the power-carrying conductor 225e is offset in the first direction from the PV structure 221 (PV-signal) of the first cell C201.

The use of the in-boundary power rails helps to increase a distance of the power rails from the PV structure 221 (PV-signal), which helps to prevent a signal-to-power short with the PV structure 221 (PV-signal) of the first cell C201 as compared to another approach in which power is supplied to a power rail located (like conductor 225d) on the second horizontal cell boundary Bxb. Further, the use of the in-boundary power rail helps to shorten a bottom contact 223b that couples the second power voltage V02 (e.g., VDD) between the conductor 225e and an s/d region 209b of the second CFET 204, thus allowing for a greater spacing and less chance of a short circuit between the bottom contact 223b and conductive structures such as the PV-signal structure 221 in the first cell C201.

As discussed above, the semiconductor device 200 includes the PV-signal structure 221 in the insulating structure 222, which in some embodiments is, or is included in, a gate-cutting structure. The PV-signal structure 221 can be made relatively large and/or with a lower aspect ratio relative to a deep via (DV) structure of another approach, thus providing a lower-resistance signal path as compared to using the DV structure of another approach. Further, since the DV structure of another approach is located between adjacent gate structures, the DV structure imposes limitations on gate pitch because of the need to maintain adequate spacing between the DV and the adjacent gate structures to avoid a DV-to-gate short circuit. In contrast, the PV-signal structure 221 can be located in a gate-cutting structure at ends of gate structures, thereby avoiding the DV limitation on gate spacing and helping to reduce a cell footprint and overall die area, and/or allow for relaxed process requirements. For example, whereas implementing a DV between adjacent gate structures may require a gate pitch that is fifteen times or more of a gate width, the semiconductor device 200 can have gate structures 208 spaced in the first direction with a gate pitch of less than fifteen times the gate width. Further, the semiconductor device 200 includes the in-boundary power rail 225c, which helps to minimize the possibility of power-signal short circuit between the in-boundary power rail 225c and another conductive structure, e.g., a signal-carrying conductor, in the second cell C202.

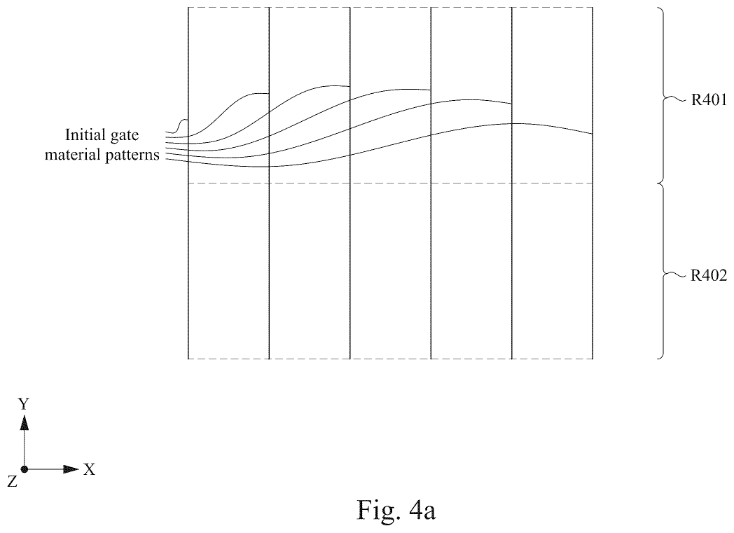

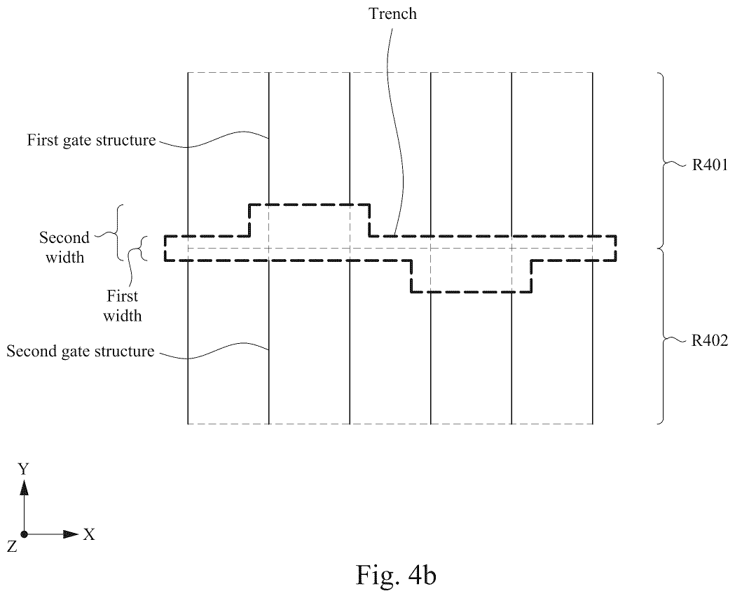

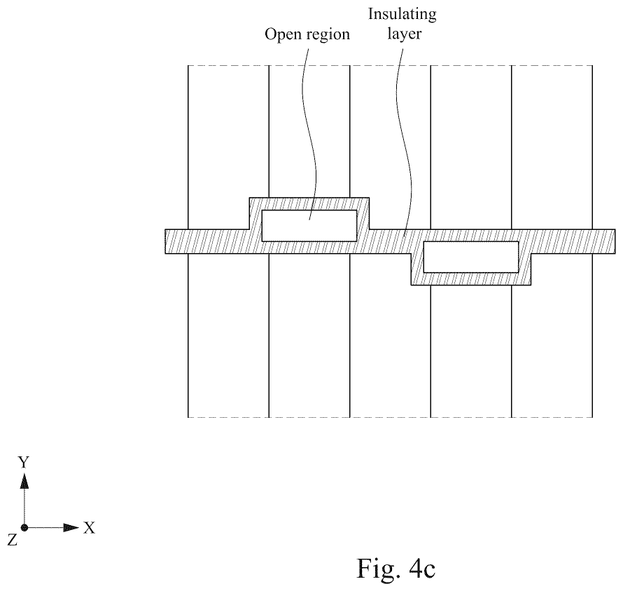

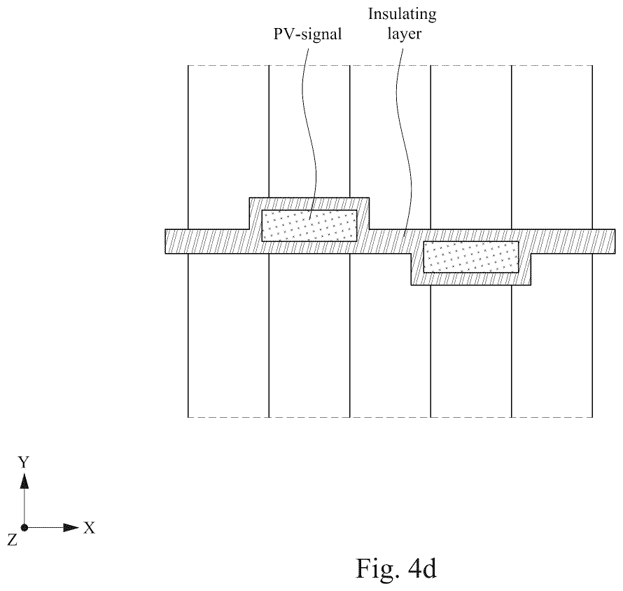

FIG. 3 is a flowchart of a method 300 of fabricating a semiconductor device that includes a PV-signal via structure according to some embodiments. FIGS. 4a to 4d are plan views of intermediate structures in the formation of a semiconductor device according to the method 300 of FIG. 3.

The method 300 includes operations 302, 304, 306, and 308, which will be described in connection with FIGS. 4a, 4b, 4c, and 4d, respectively.

Referring to FIGS. 3 and 4a, in operation 302, one or more initial gate material patterns are formed to be spaced apart in the first direction. Each initial gate material pattern extends in the second direction (i.e., parallel to the Y-axis) through one or more cells that abut each other in the second direction, e.g., extending through cells in adjacent rows R401 and R402 of an integrated circuit layout. In some embodiments, a first initial gate material pattern is formed to extend through a first cell in a first row R401 and a second cell in a second row R402 abutting the first row R401, such that the first initial gate pattern corresponds to a first transistor region in the first cell and a second transistor region in the second cell. The rows R401, R402 extend in the first direction (i.e., parallel to the X-axis). In some embodiments, the first initial gate material pattern includes one or more materials forming a metal gate structure.

Next, referring to FIGS. 3 and 4b, in operation 304, a trench is formed to extend in the first direction along a cell boundary. In some embodiments, the cell boundary is a boundary at adjacent rows R401, R402 of an integrated circuit layout. In some embodiments, the cell boundary is a boundary between a first cell in a first row R401 and a second cell in a second row R402 abutting the first row R401. The trench is formed so as to section the initial gate material pattern(s) into gate structures. In some embodiments, the trench has a depth in the Z-axis direction that is equal to a height in the Z-axis direction of the initial gate material pattern(s). In some embodiments, the trench has a depth in the Z-axis direction that is greater than the height in the Z-axis direction of the initial gate material pattern(s). In some embodiments, a first initial gate material pattern extending through first and second rows R401, R402 is sectioned along a cell boundary into a first gate structure in the first cell and a second gate structure in the second cell.

The trench has different widths in the second direction (i.e., parallel to the Y-axis), e.g., a first width and a second width that is greater than the first width, with the second width corresponding to a region where a PV-signal structure will be formed. In some embodiments, the trench has the first width in the second direction for a first portion of the trench, has the second (greater) width in the second direction for a sequential second portion of the trench, and has the first width in the second direction for a sequential third portion of the trench. In some embodiments, the trench, in plan view, has a dentil-like shape in which one or more rectangular trench portions extend from a baseline trench. In other embodiments (not shown in FIG. 4b), the trench has a uniform width, e.g., the second width, with continuously parallel walls in the first direction.

Referring to FIGS. 3 and 4c, in operation 306, an insulating layer is formed or deposited on walls of the trench. In some embodiments, the insulating layer is formed on a bottom of the trench. In some embodiments, the insulating layer is formed as a conformal layer. In FIG. 4c, the insulating layer entirely fills the trench where the trench has the first width (i.e., is narrower) while leaving an open region where the trench has the second width (i.e., is wider), with the open region being a region where a conductive PV-signal structure will be formed. In other embodiments, the insulating layer entirely fills the whole trench, and a subsequent etch operation is performed to form an opening where the trench has the second width (i.e., is wider), the opening being where the PV-signal structure will be formed. In some embodiments, the insulating layer forms a cut-metal-gate (CMG) structure that isolates a first gate structure in the first transistor region in the first row R401 from a second gate structure in the second transistor region in the second row R402.

Referring to FIGS. 3 and 4d, in operation 308, a conductive via PV-signal is formed in the open region of the trench, where the trench has the second width. The conductive via PV-signal is thus completely surrounded by the insulating layer on the walls of the trench. In some embodiments, the conductive via PV-signal corresponds to the second PV structure 121 of FIG. 1. In some embodiments, the conductive via PV-signal is disposed along a horizontal cell boundary and is located between facing ends of the first gate structure and the second gate structure. In some embodiments, the conductive via PV-signal is formed as a via within a CMG structure in a region where the initial gate structure was removed between the first gate structure and the second gate structure.

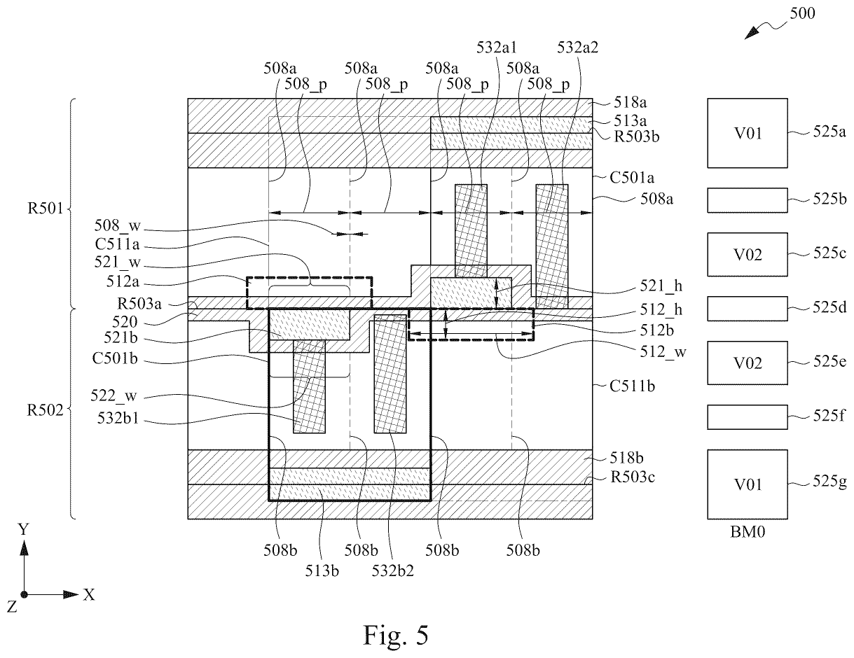

FIG. 5 is a layout diagram showing back-side layers of a semiconductor device layout 500 according to some embodiments.

In FIG. 5, the semiconductor device layout 500 according to some embodiments includes a first row R501 and a second row R502 each including an instance of a cell C501 implementing a conductive via structure for PV-signal. A cell C501 in the first row R501 is denoted as cell C501a and a cell C501 in the second row R502 is denoted as cell C501b. The cell C501a includes a PV-signal structure 521a and the cell C501b includes a PV-signal structure 521b. The PV-signal structures 521a, 521b correspond to the PV-signal structure 121 of FIG. 1 and the PV-signal structure 221 of FIG. 2. The PV-signal structures 521a, 521b may be collectively referred to as a PV-signal structure 521.

In the first row R501, a cell C511a abuts the cell C501b relative to the second direction. A portion of the cell C511a is in a reserved zone 512a that abuts the cell C501b relative to the second direction. A portion of the cell C511b is in a reserved zone 512b. In some embodiments, the reserved zone 512a is a zone that is reserved for structures other than a PV-signal structure and/or a backside contact (BMD). In some embodiments, the reserved zone 512b is a zone that is reserved for structures other than a PV-signal structure and/or other than a backside contact. The reserved zones 512a, 512b may be collectively referred to as a reserved zone 512. The reserved zone 512 corresponds to the region C202_r1 of FIG. 2.

The reserved zone 512a in the first row R501 is aligned with the PV-signal structure 521b of the cell C501b in the second row R502. The reserved zone 512b in the second row R502 is aligned with the PV-signal structure 521a of the cell C501a in the first row R501. In the semiconductor device layout 500, the reserved zones are located to be aligned with PV-signal structures in abutting cells so as to avoid the possibility of a signal-to-signal short with a neighboring PV-signal structure and/or a backside contact.

The reserved zone 512 has a width 512_w in the first direction and has a height 512_h in the second direction (row height direction). In some embodiments, the width 512_w of the reserved zone 512 is about 1.5 CPP. In some embodiments, the height 512_h of the reserved zone 512 is approximately equal to a height 521_h of the PV-signal structure 521 in the second direction. In other embodiments, the height 512_h is greater than or lesser than the height 521_h of the PV-signal structure 521. In some embodiments, the height 512_h is about 0.5 CPP. In other embodiments, the height 512_h is less than 0.5 CPP. In some embodiments, the height 512_h is at least about 0.4 CPP.

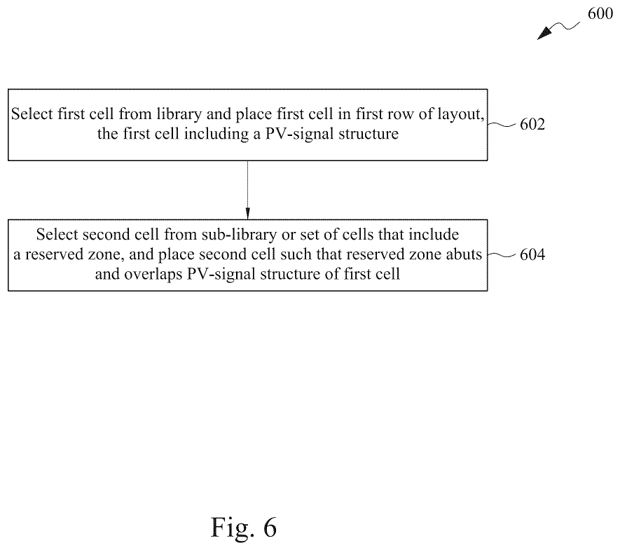

FIG. 6 is a flowchart of a method 600 of designing a semiconductor device layout according to some embodiments.

Referring to FIG. 6, in some embodiments, a method 600 of designing a semiconductor device includes a first operation 602 of selecting a first cell from a library of standard cells, and placing the first cell in a first row of a layout, the first cell including an instance of a PV-signal structure (e.g., PV-signal structures 121, 221, or 521). An example of the first operation 602 is selecting the cell C501b from the library and placing the cell C501b in row R502. The method 600 further includes a second operation 604 of selecting a second cell from the library, and placing the second cell in a second, adjacent row of the layout to abut the first cell along the second direction, such that a reserved zone (e.g., the region C202_r1 or reserved zone 512) of the second cell abuts and overlaps the PV-signal structure of the first cell. In some embodiments, the second cell is selected from among a sub-library or set of cells that each include a reserved zone that is reserved for structures other than a PV-signal structure and/or a backside contact. Placing the second cell includes arranging the reserved zone of the second cell to overlap with the PV-signal structure of the first cell. An example of the second operation 604 is selecting the cell C511a from a sub-library or set of cells that each include the reserved zone 512, and placing the cell C511a in row R501 to abut the cell C501b such that the reserved zone 512a of the cell C511a overlaps with the PV-signal structure 521b of the cell C501b. In some embodiments, placing the cell C511a includes placing the cell C511a such that a center of the reserved zone 512a as determined along the first direction is aligned with a center of the PV-signal structure as determined along the first direction. In some embodiments, placing the cell C511a includes placing the cell C511a such that such that boundaries of the reserved zone 512a extending parallel to the second direction are aligned with boundaries of the PV-signal structure 521 extending parallel to the second direction.

Referring again to FIG. 5, the PV-signal structure 521a is configured to couple a signal to an s/d region of a transistor, e.g., a lower transistor of a CFET, in the cell C501a by way of a bottom contact 523a1 in a BMD layer. In some embodiments, the bottom contact 523a1 is a drain contact of a lower transistor of a CFET in the cell C501a, and a bottom contact 523a2 in the BMD layer is a source contact of the lower transistor of the CFET in the cell C501a. The PV-signal structure 521b is configured to couple a signal to an s/d region of a transistor, e.g., a lower transistor of a CFET, in the cell C501b by way of a bottom contact 523b1 in the BMD layer. In some embodiments, the bottom contact 523b1 is a drain contact of a lower transistor of a CFET in the cell C501b, and a bottom contact 523b2 in the BMD layer is a source contact of the lower transistor of the CFET in the cell C501b.

Cells C501a and C501b are shown as having the same structure while being rotated in the X-Y plane by 180°, but this is merely for the sake of explanation. Semiconductor layouts according to some embodiments include only one of the cells C501a or C501b or include the cells C501a and C501b in different positions and/or rows relative to each other, or the like.

In FIG. 5, locations of gate structures 508a in the cells C511a, C501a of the first row R501 and locations of gate structures 508b in the cells C501b, C511b of the second row R502 are shows by dashed lines extending in the second direction (the gate structures 508a and 508b may be collectively referred to as gate structures 508). The gate structures 508 are shown in FIG. 5 as being disposed at a uniform gate pitch 508_p in the first direction (according to some embodiments the gate pitch is a center-to-center distance of immediately adjacent first and second gate structures, where “immediately adjacent” means no intervening or third gate structure is present between the first and second gate structures). In some embodiments, each of the gate structures 508 has a uniform width 508_w in the first direction.

In some embodiments, the gate structures 508a, 508b are formed from initial gate material patterns that extend continuously between the first row R501 and the second row R502, the initial gate material patterns being cut to isolate the gate structures 508a from the gate structures 508b by an insulating gate-cutting structure 520 that extends along a common row boundary R503a that is common to each of the first row R501 and the second row R502. In some embodiments, gate structures in a row above the first row R501 are isolated from the gate structure 508a in the first row R501 by an insulating gate-cutting structure 518a that extends along a row boundary R503b, and gate-cutting structures in a row under the second row R502 are isolated from the gate structures 508b in the second row R502 by an insulating gate-cutting structure 518b that extends along a row boundary R503c. In some embodiments, the gate-cutting structures 520, 518a, and/or 518b are cut-metal-gate (CMG) structures.

In some embodiments, the insulating structure 122 of FIG. 1 and/or the insulating structure 222 of FIG. 2 correspond to a portion of the gate-cutting structure 520. In some embodiments, forming the gate-cutting structure 520 includes forming a trench (the trench cutting or separating the initial gate material patterns so as to cut the gate structures 508a from the gate structures 508b), forming an insulating layer, and forming PV-signal structures in openings in the insulating layer, in a manner similar to that described in connection with FIGS. 4b-4d, such that the PV-signal structures 521a, 521b are each surrounded by the insulating material of the gate-cutting structure 520.

In some embodiments, the insulating structure 114 of FIG. 1 and/or insulating structures 214a, 214b of FIG. 2 correspond to a portion of the gate-cutting structures 518a and/or 518b. In some embodiments, forming the gate-cutting structures 518a, 518b includes forming a trench, forming an insulating layer, and forming a PV-power structure in an opening in the insulating layer, in a manner similar to that described in connection with FIGS. 4b-4d, such that PV-power structures 513a and 513b are respectively surrounded by the gate-cutting structure 518a, 518b. In FIG. 5, the PV-power structures 513a, 513b each extend for a full width of the corresponding cell in the first direction. In other embodiments, the PV-power structures 513a, 513b are longer or shorter in the first direction.

Each of the PV-signal structures 521a, 521b has a width 521_w in the first direction. In some embodiments, the width 521_w is sufficient to span two adjacent gate structures 508, e.g., the width 521_w is equal to or greater than the sum of the pitch 508_p and the width 508_w. In other embodiments, the width 521_w is less than the pitch 508_p. In some embodiments, the width 521_w is the same for each of the PV-signal structures 521a, 521b, whereas in other embodiments the width 521_w of the PV-signal structure 521a is different from that of the PV-signal structure 521b.

The portions of the gate-cutting structure 520 surrounding the PV-signal structures 521a, 521b have a width 522_w in the first direction. The width 522_w is greater than the width 521_w. In some embodiments (not shown in FIG. 5), the width 522_w corresponds to the sum of the pitch 508_p and the width 508_w, and in other embodiments, the width 522_w is less than the pitch 508_p. In some embodiments, the width 522_w is the same for each of the PV-signal structures 521a, 521b, whereas in other embodiments the width 522_w of the portion of the gate-cutting structure 520 surrounding the PV-signal structure 521a is different from that of the portion of the gate-cutting structure 520 surrounding the PV-signal structure 521b.

The first and second rows R501, R502 include conductors 525a, 525b, 525c, 525d, 525e, 525f, and 525g in a first backside conductive layer BM0. The conductors 525a-525g generally extend parallel to the X-axis direction. The conductor 525d is on a common boundary of the first row R501 and the second row R502. The conductor 525a is configured to couple the first power voltage V01 (e.g., one of VSS and VDD, e.g., VSS) to the cells C511a and C501a in the first row R501. The conductor 525c is configured to couple the second power voltage V02 (e.g., the other of VSS and VDD, e.g., VDD) to the cells C511a and C501a in the first row R501. The conductor 525c is spaced apart in the Y-axis direction from the common row boundary of the rows R501 and R502, such that the conductor 525c carrying V02 does not overlap or abut the common row boundary. Likewise, the conductor 525e is configured to couple the second power voltage V02 to the cells C501b and C511b in the second row R502, and is spaced apart in the Y-axis direction from the common row boundary of the rows R501 and R502, such that the conductor 525e carrying the second power voltage V02 does not overlap or abut the common row boundary. The cells C511a, C501a, C501b, and C511b thus include in-boundary power rails in the first backside conductive layer BM0 for the second power voltage V02. The conductor 525g is configured to couple the first power voltage V01 to the cells C501b and C511b in the second row R502. The conductors 525b, 525f are configured to couple signals to the cells C511a, C501a, C501b, and/or C511b.

FIG. 7a is a schematic diagram of an and-or-invert (AOI) circuit 700a. FIG. 7b is layout diagram of a front-side layout 700b-1 of a semiconductor device implementing the AOI circuit 700a according to some embodiments. FIG. 7c is a layout diagram of a back-side layout 700b-2 of a semiconductor device implementing the AOI circuit 700a according to some embodiments.

Referring to FIG. 7a, the AOI circuit 700a is implemented with four CFETs. CFET A1 includes a PMOS transistor and an NMOS transistor. CFET A2 also includes a PMOS transistor and an NMOS transistor. CFET B1 also includes a PMOS transistor and an NMOS transistor. CFET B2 includes a PMOS transistor and an NMOS transistor. In FIGS. 7b-7c, four CFETS A1, A2, B1, and B2 correspond to the four CFETS A1, A2, B1, and B2 in FIG. 7a. In FIGS. 7b and 7c, the CFETs A1, A2, B1, and B2 are implemented with PMOS transistors as lower transistors and NMOS transistors as upper transistors. In the top portion of the AOI circuit 700a, PMOS transistors of CFETs B1 and A1 are coupled together in series, PMOS transistors of CFETs B2 and A2 are coupled together in series, and the PMOS transistors of CFETs B1, Al are coupled in parallel with the PMOS transistors of CFETs B2, A2, with the PMOS transistors of the CFETs B1 and B2 having sources commonly connected to VDD and drains tied together, and the PMOS transistors of CFETs A1 and A2 having drains commonly connected to a node ZN. Further, in the bottom portion of the AOI circuit 700a, NMOS transistors of CFETs A1 and A2 are coupled together in series, NMOS transistors of CFETs B1 and B2 are coupled together in series, and the NMOS transistors of CFETs A1, A2 are coupled in parallel with the NMOS transistors of CFETs B1, B2, with the NMOS transistors of CFETs A1 and B1 being commonly connected to a node ZN, and the NMOS transistors of CFETs A2, B2 being commonly connected to VSS. A common-gate configuration is used with the input signal being supplied via the front side.

Referring to FIG. 7c, the layout diagram 700b-2 includes an in-boundary power rail 710 in a first backside conductive layer BM0, which is configured to couple power voltage VDD to the AOI circuit 700a in row n by way of a PV-power structure 713c that extends in the first direction and vertically overlaps (in the Z-axis direction) the in-boundary power rail 710.

Further, referring to FIGS. 7b and 7c, the layout diagrams 700b-1, 700b-2 include a PV-signal structure 721 in an insulating gate-cutting structure 720. In some embodiments, the gate-cutting structure 720 is a CMG structure. The PV-signal structure 721 has a first side 721_1 aligned with a row boundary 703 that is common to row n and an adjacent upper row, row n-1.

A portion of a cell C711 in row n-1 is in a reserved zone 712 having a first side 712_1 that is oriented along the first direction and abuts the first side 721_1 of the PV-signal structure 721 along the row boundary 703, a second side 712_2 that is oriented along the first direction and spaced apart from the first side 712_1 in the second direction by a height 712_h, a third side 712_3 that is oriented along the second direction, and a fourth side 712_4 that is oriented along the second direction and spaced apart in the first direction from the third side 712_3 by a width 712_w. In some embodiments, the width 712_w of the reserved zone 712 is about 1.5 CPP. In some embodiments, the height 712_h of the reserved zone is approximately equal to a height 721_h of the PV-signal structure 721 in the second direction. In other embodiments, the height 712_h is greater than or lesser than the height 721_h of the PV-signal structure 721. In some embodiments, the height 712_h is about 0.5 CPP. In other embodiments, the height 712_h is less than 0.5 CPP. In some embodiments, the height 712_h is at least about 0.4 CPP.

The layout diagrams 700b-1, 700b-2 include a PV-power structure 713a and a second PV-power structure 713b in an insulating gate-cutting structure 718. The PV-power structures 713a, 713b are configured to couple power voltage VSS to the AOI circuit 700a in row n.

The layout diagrams 700b-1, 700b-2 include gate structures 708 extending in the second direction between the gate-cutting structure 720 and the gate-cutting structure 718. Signals driving ones of the gate structures 708 are supplied to conductors 716 extending in the first direction, which are connected to ones of the gate structures 708 by vias 724.

Source/drain regions of the CFETs are contacted by conductive upper contacts 715 extending in the second direction (which may be referred to as MD structures in the front side) and conductive lower contacts 719 extending in the second direction (which may be referred to as BMD structures in the back side).

As discussed above, the layout diagrams 700b-1, 700b-2 include the PV-signal structure 721 in the gate-cutting structure 720. The PV-signal structure 721 can be made relatively large and/or with a lower aspect ratio relative to a deep via (DV) structure of another approach, thus providing a lower-resistance signal path as compared to another approach using the DV structure. Further, since the DV structure of another approach is located between adjacent gate structures, the DV structure imposes limitations on gate pitch because of the need to maintain adequate spacing between the DV and the adjacent gate structures to avoid a DV-to-gate short circuit. In contrast, the PV-signal structure 721 is located in a gate-cutting structure at ends of gate structures, thereby avoiding the DV limitation on gate spacing and helping to reduce a cell footprint and overall die area, and/or allow for relaxed process requirements. For example, whereas implementing a DV between adjacent gate structures may require a gate pitch that is fifteen times or more of a gate width, the layout diagrams 700b-1, 700b-2 can have the gate structures 708 spaced in the first direction with a gate pitch of less than fifteen times the gate width. Further, the layout diagrams 700b-1, 700b-2 include the in-boundary power rail 710, which helps to minimize the possibility of power-signal short circuit between the in-boundary power rail 710 and another conductive structure, e.g., a signal-carrying conductor, in a circuit in adjacent row n-1.

Although advantages of the PV-signal structure 721 in the gate-cutting structure 720 and in-boundary power rail 710 are described above in connection with the AOI circuit 700a, it will be appreciated that these advantages are not limited to the case of the AOI circuit 700a, and the in-boundary power rail and/or the PV-signal structure in the gate-cutting structure are generally applicable in any suitable circuit.

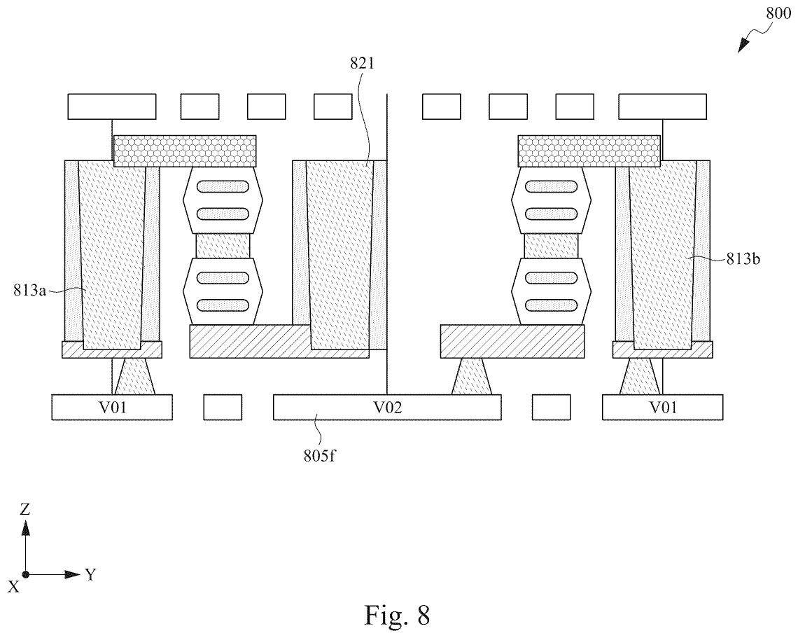

FIG. 8 is a cross-sectional view of a semiconductor device 800 according to some embodiments.

In FIG. 8, the BM0 conductors 225c, 225d, and 225e described above in connection with FIG. 2 are modified to be a single large BM0 power rail 805f that supplies the second power voltage V02 (e.g., VSS or VDD, e.g., VDD). PV-signal structure 821 is configured to convey a signal and corresponds to the PV-signal structure 221 of FIG. 2. PV-power structures 813a and 813b are configured to supply the first power voltage V01 (e.g., VDD or VSS, e.g., VSS) and correspond to the PV-power structures 213a and 213b of FIG. 2. Other features of FIG. 8 likewise correspond to those described above in connection with FIG. 2.

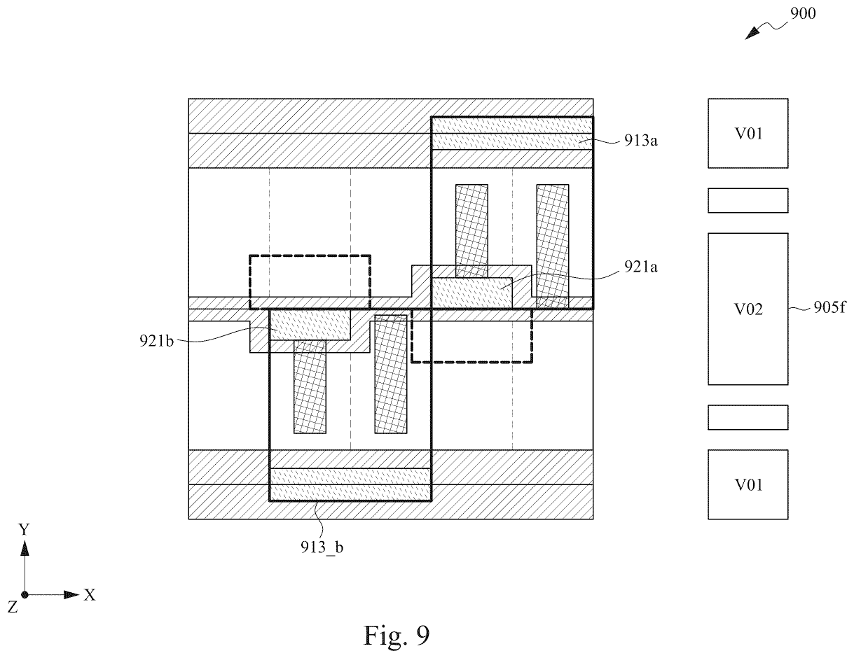

FIG. 9 is a layout diagram showing back-side layers of a semiconductor device layout 900 according to some embodiments.

In FIG. 9, the BM0 conductors 525c, 525d, and 525e described above in connection with FIG. 5 are modified to be a single large BM0 power rail 905f that supplies the second power voltage V02 (e.g., VSS or VDD, e.g., VDD). PV-signal structures 921a and 921b are configured to convey signals and correspond to the PV-signal structures 521a and 521b of FIG. 5. PV-power structures 913a and 913b are configured to supply the first power voltage V01 (e.g., VDD or VSS, e.g., VSS) and correspond to the PV-power structures 513a and 513b of FIG. 5. Other features of FIG. 9 likewise correspond to those described above in connection with FIG. 5.

As described above in connection with FIGS. 8 and 9, a single large backside power rail 805f and/or 905f can be implemented to supply a power voltage such as VDD. Increasing the size of a backside power rail that is common to adjacent cells, as in FIGS. 8 and 9, reduces resistance of the power rail, increases routing flexibility, and simplifies connections to the power rail.

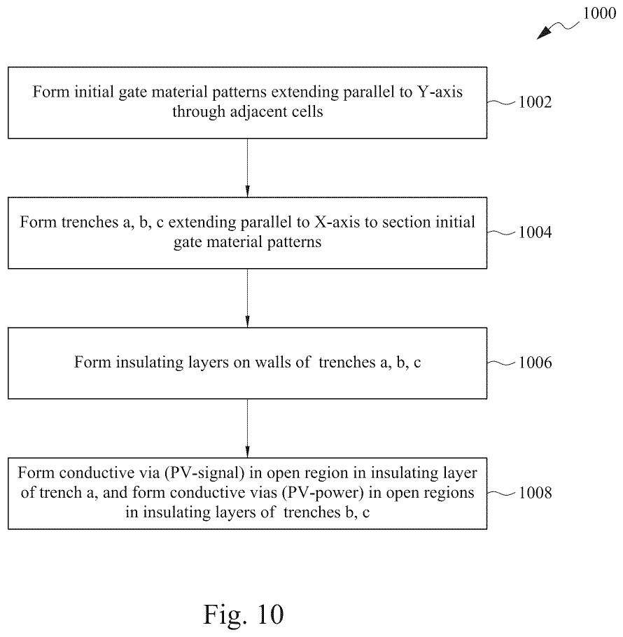

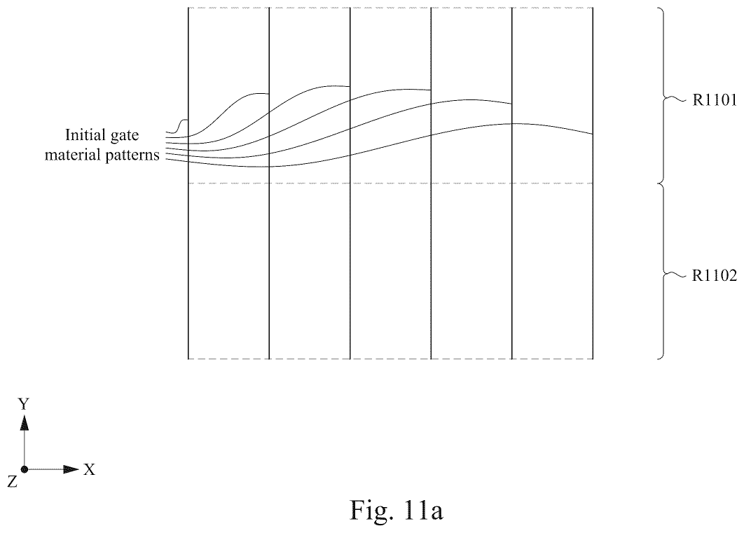

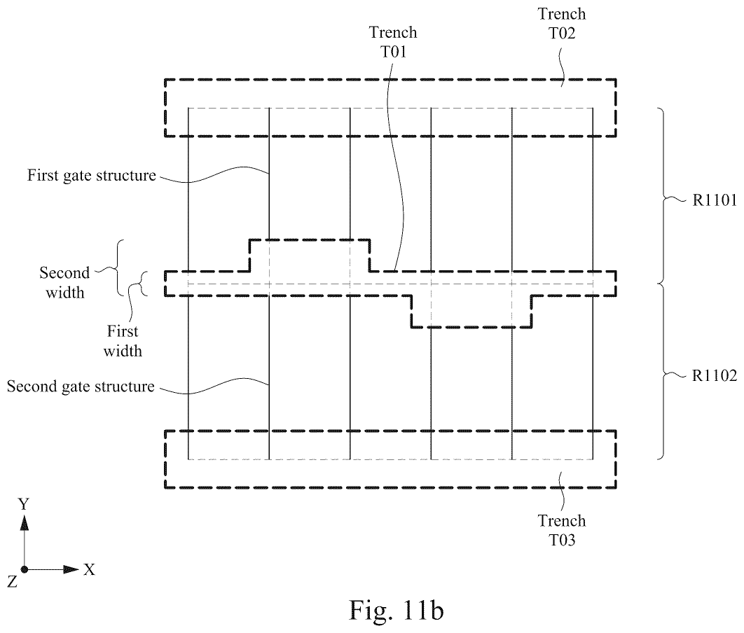

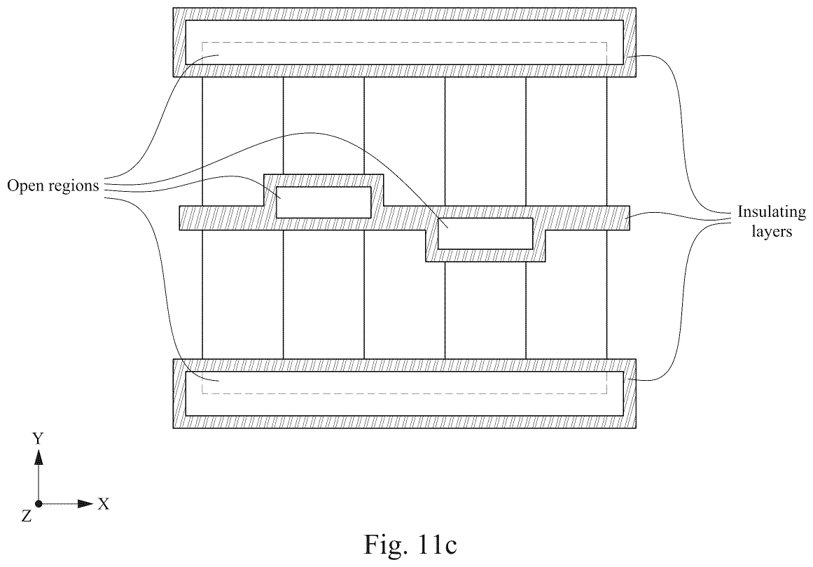

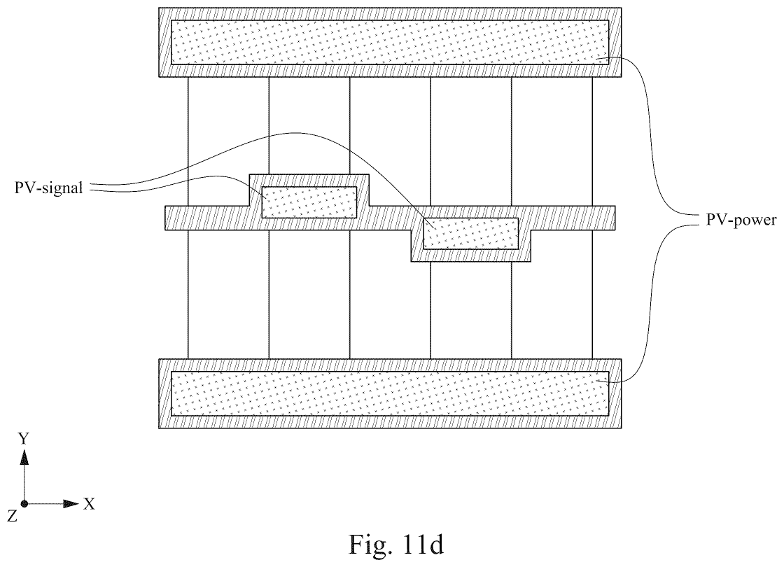

FIG. 10 is a flowchart of a method 1000 of fabricating a semiconductor device that includes PV-signal and PV-power via structures according to some embodiments. FIGS. 11a to 11d are schematic plan views of intermediate structures in the formation of a semiconductor device according to the method 1000 of FIG. 10.

The method 1000 includes operations 1002, 1004, 1006, and 1008, which will be described in connection with FIGS. 11a, 11b, 11c, and 11d, respectively.

Referring to FIGS. 10 and 11a, in operation 1002, one or more initial gate material patterns are formed. Each initial gate material pattern extends in the second direction (i.e., parallel to the Y-axis) through one or more cells that abut each other in the Y-axis direction, e.g., through cells in adjacent rows R1101 and R1102 of an integrated circuit layout. In some embodiments, a first initial gate material pattern is formed to extend through a first cell in a first row R1101 and a second cell in a second row R1102 abutting the first row R1101, such that the first initial gate pattern corresponds to a first transistor region in the first cell and a second transistor region in the second cell. The rows R1101, R1102 extend in the first direction (i.e., parallel to the X-axis). In some embodiments, the first initial gate material pattern includes one or more materials for forming a metal gate structure.

Next, referring to FIGS. 10 and 11b, in operation 1004, three trenches T01, T02, and T03 are formed to extend in the first direction along cell boundaries of the first and second rows R1101, 1102, with trench T01 being between trenches T02 and T03 relative to the second direction. The trenches T01-T03 formed so as to section the initial gate material pattern(s) into gate structures.

The trench T01 has different widths in the second direction (i.e., parallel to the Y-axis), e.g., a first width and a second width that is greater than the first width, with the second width corresponding to a region where a PV-signal will be formed. In FIG. 11b, the trench T01 has the first width in the second direction for a first portion of the trench (at the left-hand side of FIG. 11b), has the second (greater) width in the second direction for a sequential second portion of the trench, has the first width in the second direction for a sequential third portion of the trench, has the second (greater) width in the second direction for a sequential fourth portion of the trench, and has the first width in the second direction for a sequential fifth portion of the trench (at the right-hand side of FIG. 11b).

On the other hand, the trenches T02 and T03 have a uniform width, e.g., the second width, with continuously parallel walls in the first direction.

Referring to FIGS. 10 and 11c, in operation 1106, an insulating layer is formed or deposited on walls of the trenches T01-T03. In some embodiments, the insulating layer is formed on a bottom of the trenches T01-T03.

In the first trench T01, the insulating layer entirely fills the trench T01 where the trench T01 has the first width (i.e., is narrower) while leaving an open region where the trench T01 has the second width (i.e., is wider), with the open region being a region where a PV-signal structure will be formed. In other embodiments, the insulating layer entirely fills the whole of trench T01, and a subsequent etch operation is performed to form an opening where the trench T01 has the second width (i.e., is wider), with the opening being where a PV-signal will be formed. In some embodiments, the insulating layer forms a cut-metal-gate (CMG) structure in the trench T01.

The insulating layer leaves an open region in each of the second and third trenches T02, T03, the open regions being regions where conductive PV-power structures will be formed. In other embodiments, the insulating layer entirely fills the whole of the second and third trenches T02, T03, and a subsequent etch operation is performed to form openings where the PV-power structures will be formed. In some embodiments, the insulating layer forms a cut-metal-gate (CMG) structure in the trench T01.

Referring to FIGS. 10 and 11d, in operation 1108, conductive via structures (PV-signal) are formed in the open regions of the first trench T01, where the first trench T01 has the second width. The conductive via structures (PV-signal) are thus completely surrounded by the insulating layer on the walls of the first trench T01.

Also in operation 1108, conductive via structures (PV-power) are formed in the open regions of the second and third trenches T02, T03. The conductive via structures (PV-power) are thus completely surrounded by the insulating layer on the walls of the second and third trenches T02, T03. In FIG. 11d, the conductive via structures (PV-power) formed in the second and third trenches T02, T03 extend continuously across ends of a plurality of gate structures, and are longer in the first direction than the conductive via structures (PV-signal) formed in the first trench T01. In other embodiments, the conductive via structures (PV-power) formed in the second and third trenches T02, T03 are discontinuous in the first direction, and/or are shorter in the first direction than the conductive via structures (PV-signal) formed in the first trench T01.

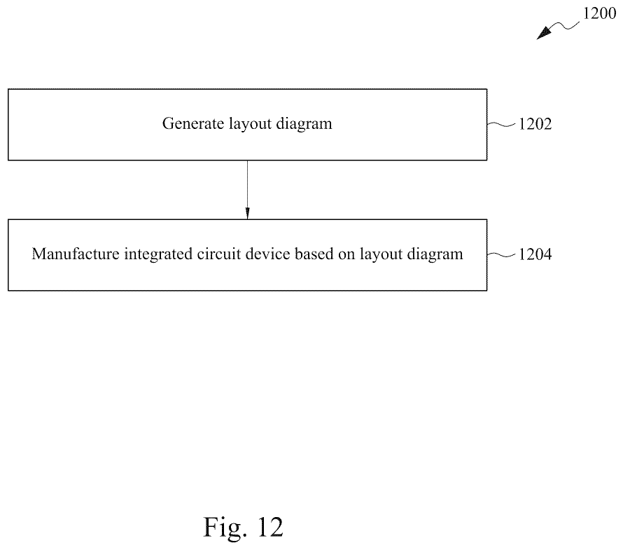

FIG. 12 is a flowchart of a method 1200 of manufacturing a semiconductor device according to some embodiments.

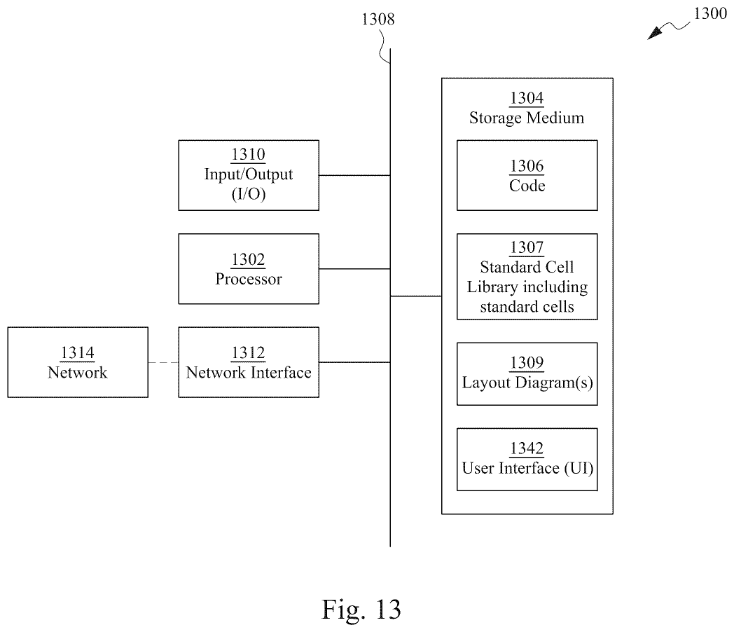

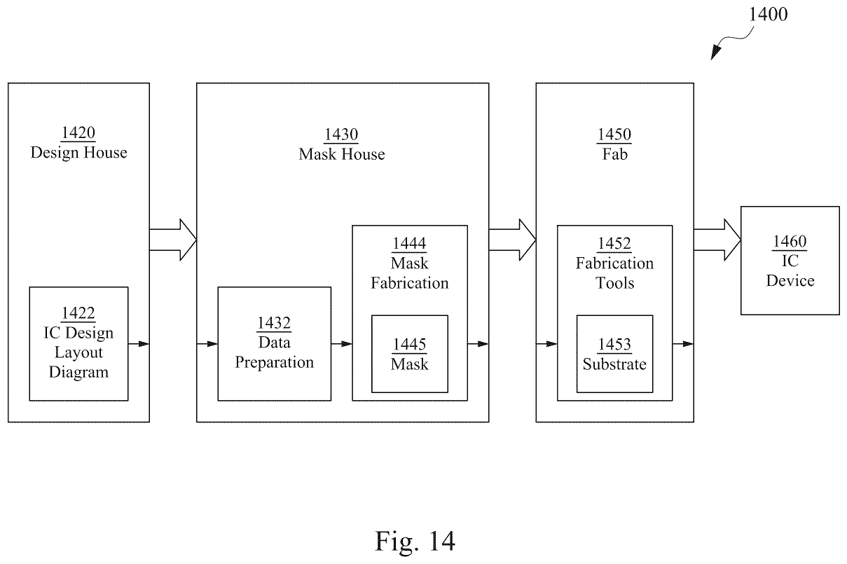

Method 1200 is implementable, for example, using EDA system 1300 (FIG. 13, discussed below) and an integrated circuit (IC), manufacturing system 1400 (FIG. 14, discussed below) according to some embodiments. Examples of a semiconductor device which can be manufactured according to method 1200 include semiconductor devices 100, 200, 400, 500, 700b, 800, 900, and 1100, or the like.

In FIG. 12, method 1200 includes blocks 1202-1204. At block 1202, a layout diagram is generated which, among other things, includes one or more of layout diagrams disclosed herein, such as layout diagrams 500, 700b-1, 700b-2, 900, or the like. Block 1202 is implementable, for example, using EDA system 1300 (FIG. 13, discussed below) according to some embodiments. In some embodiments, block 1202 includes generating shapes corresponding to structures in a semiconductor diagram which are to be represented.

At block 1204, based on the layout diagram, at least one of (A) one or more photolithographic exposures are made or (B) one or more semiconductor masks are fabricated or (C) one or more components in a layer of an integrated circuit (IC) device, e.g., a semiconductor device such as the semiconductor devices 100, 200, or 800, are fabricated. See discussion below of FIG. 14.

FIG. 13 is a block diagram of an electronic design automation (EDA) system 1300 according to some embodiments.

In some embodiments, EDA system 1300 includes an automatic placement and routing (APR) system. Methods described herein of designing layout diagrams represent wire routing arrangements, in accordance with one or more embodiments, are implementable, for example, using EDA system 1300 according to some embodiments.

In some embodiments, EDA system 1300 is a general purpose computing device including a hardware processor 1302 and a non-transitory, computer-readable storage medium 1304. Computer-readable storage medium 1304, amongst other things, is encoded with, i.e., stores, computer program code 1306, i.e., a set of executable instructions. Execution of instructions 1306 by processor 1302 represents (at least in part) an EDA tool which implements a portion or all of the methods described herein in accordance with one or more embodiments (hereinafter, the noted processes and/or methods).

Processor 1302 is electrically coupled to computer-readable storage medium 1304 via a bus 1308. Processor 1302 is also electrically coupled to an I/O interface 1310 by bus 1308. A network interface 1312 is also electrically connected to processor 1302 via bus 1308. Network interface 1312 is connected to a network 1314, so that processor 1302 and computer-readable storage medium 1304 are capable of connecting to external elements via network 1314. Processor 1302 is configured to execute computer program code 1306 encoded in computer-readable storage medium 1304 in order to cause EDA system 1300 to be usable for performing a portion or all of the noted processes and/or methods. In one or more embodiments, processor 1302 is a central processing unit (CPU), a multi-processor, a distributed processing system, an application specific integrated circuit (ASIC), and/or a suitable processing unit.

In one or more embodiments, computer-readable storage medium 1304 is an electronic, magnetic, optical, electromagnetic, infrared, and/or a semiconductor system (or apparatus or device). For example, computer-readable storage medium 1304 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1304 includes a compact disk-read only memory (CD-ROM), a compact disk-read/write (CD-R/W), and/or a digital video disc (DVD).

In one or more embodiments, computer-readable storage medium 1304 stores computer program code 1306 configured to cause EDA system 1300 (where such execution represents (at least in part) the EDA tool) to be usable for performing a portion or all of the noted processes and/or methods. In one or more embodiments, computer-readable storage medium 1304 also stores information which facilitates performing a portion or all of the noted processes and/or methods. In one or more embodiments, computer-readable storage medium 1304 stores library 1307 of standard cells including such standard cells as disclosed herein. In one or more embodiments, computer-readable storage medium 1304 stores one or more layout diagrams 1309 corresponding to one or more layouts disclosed herein.

EDA system 1300 includes I/O interface 1310. I/O interface 1310 is coupled to external circuitry. In one or more embodiments, I/O interface 1310 includes a keyboard, keypad, mouse, trackball, trackpad, touchscreen, and/or cursor direction keys for communicating information and commands to processor 1302.

EDA system 1300 also includes network interface 1312 coupled to processor 1302. Network interface 1312 allows EDA system 1300 to communicate with network 1314, to which one or more other computer systems are connected. Network interface 1312 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EDA systems 1300.

EDA system 1300 is configured to receive information through I/O interface 1310. The information received through I/O interface 1310 includes one or more of instructions, data, design rules, libraries of standard cells, and/or other parameters for processing by processor 1302. The information is transferred to processor 1302 via bus 1308. EDA system 1300 is configured to receive information related to a user interface (UI) through I/O interface 1310. The information is stored in computer-readable storage medium 1304 as UI 1342.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1300. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 14 is a block diagram of an integrated circuit (IC) manufacturing system 1400, and an IC manufacturing flow associated therewith according to some embodiments. In some embodiments, based on a layout diagram, at least one of (A) one or more semiconductor masks or (B) at least one component in a layer of a semiconductor integrated circuit is fabricated using IC manufacturing system 1400.

In FIG. 14, IC manufacturing system 1400 includes entities, such as a design house 1420, a mask house 1430, and an IC manufacturer/fabricator (fab) 1450, that interact with one another in the design, development, and manufacturing cycles and/or services related to manufacturing an IC device 1460. The entities in IC manufacturing system 1400 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1420, mask house 1430, and IC fab 1450 is owned by a single larger company. In some embodiments, two or more of design house 1420, mask house 1430, and IC fab 1450 coexist in a common facility and use common resources.

Design house (or design team) 1420 generates an IC design layout diagram 1422. IC design layout diagram 1422 includes various geometrical patterns designed for an IC device 1460. The geometrical patterns correspond to patterns of metal, oxide, or semiconductor layers that make up the various components of IC device 1460 to be fabricated. The various layers combine to form various IC features. For example, a portion of IC design layout diagram 1422 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1420 implements a proper design procedure to form IC design layout diagram 1422. The design procedure includes one or more of logic design, physical design or place and route. IC design layout diagram 1422 is presented in one or more data files having information of the geometrical patterns. For example, IC design layout diagram 1422 can be expressed in a GDSII file format or DFII file format.

Mask house 1430 includes mask data preparation 1432 and mask fabrication 1444. Mask house 1430 uses IC design layout diagram 1422 to manufacture one or more masks 1445 to be used for fabricating the various layers of IC device 1460 according to IC design layout diagram 1422. Mask house 1430 performs mask data preparation 1432, where IC design layout diagram 1422 is translated into a representative data file (RDF). Mask data preparation 1432 provides the RDF to mask fabrication 1444. Mask fabrication 1444 includes a mask writer. A mask writer converts the RDF to an image on a substrate, such as a mask (reticle) 1445 or a substrate 1453, e.g., a semiconductor wafer 1453. The IC design layout diagram 1422 is manipulated by mask data preparation 1432 to comply with particular characteristics of the mask writer and/or requirements of IC fab 1450. In FIG. 14, mask data preparation 1432 and mask fabrication 1444 are illustrated as separate elements. In some embodiments, mask data preparation 1432 and mask fabrication 1444 can be collectively referred to as mask data preparation.

In some embodiments, mask data preparation 1432 includes optical proximity correction (OPC) which uses lithography enhancement techniques to compensate for image errors, such as those that can arise from diffraction, interference, other process effects and the like. OPC adjusts IC design layout diagram 1422. In some embodiments, mask data preparation 1432 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1432 includes a mask rule checker (MRC) that checks the IC design layout diagram 1422 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1422 to compensate for photolithographic implementation effects during mask fabrication 1444, which may undo part of the modifications performed by OPC in order to meet mask creation rules.

In some embodiments, mask data preparation 1432 includes lithography process checking (LPC) that simulates processing that will be implemented by IC fab 1450 to fabricate IC device 1460. LPC simulates this processing based on IC design layout diagram 1422 to create a simulated manufactured device, such as IC device 1460. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1422.

It should be understood that the above description of mask data preparation 1432 has been simplified for the purpose of clarity. In some embodiments, mask data preparation 1432 includes additional features such as a logic operation (LOP) to modify the IC design layout diagram 1422 according to manufacturing rules. Additionally, the processes applied to IC design layout diagram 1422 during mask data preparation 1432 may be executed in a variety of different orders.

After mask data preparation 1432 and during mask fabrication 1444, a mask 1445 or a group of masks 1445 are fabricated based on the modified IC design layout diagram 1422. In some embodiments, mask fabrication 1444 includes performing one or more lithographic exposures based on IC design layout diagram 1422. In some embodiments, an electron-beam (e-beam) or a mechanism of multiple e-beams is used to form a pattern on a mask (photomask or reticle) 1445 based on the modified IC design layout diagram 1422. Mask 1445 can be formed in various technologies. In some embodiments, mask 1445 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1445 includes a transparent substrate (e.g., fused quartz) and an opaque material (e.g., chromium) coated in the opaque regions of the binary mask. In another example, mask 1445 is formed using a phase shift technology. In a phase shift mask (PSM) version of mask 1445, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1444 is used in a variety of processes. For example, such a mask(s) is used in an ion implantation process to form various doped regions in semiconductor wafer 1453, in an etching process to form various etching regions in semiconductor wafer 1453, and/or in other suitable processes.

IC fab 1450 is an IC fabrication business that includes one or more manufacturing facilities for the fabrication of a variety of different IC products. In some embodiments, IC fab 1450 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1450 includes fabrication tools 1452 configured to execute various manufacturing operations on semiconductor wafer 1453 such that IC device 1460 is fabricated in accordance with the mask(s), e.g., mask 1445. In various embodiments, fabrication tools 1452 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1450 uses mask(s) 1445 fabricated by mask house 1430 to fabricate IC device 1460. Thus, IC fab 1450 at least indirectly uses IC design layout diagram 1422 to fabricate IC device 1460. In some embodiments, semiconductor wafer 1453 is fabricated by IC fab 1450 using mask(s) 1445 to form IC device 1460. In some embodiments, the IC fabrication includes performing one or more lithographic exposures based at least indirectly on IC design layout diagram 1422. Semiconductor wafer 1453 includes a silicon substrate or other proper substrate having material layers formed thereon. Semiconductor wafer 1453 further includes one or more of various doped regions, dielectric features, multilevel interconnects, and the like (formed at subsequent manufacturing steps).

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless otherwise specified.

In some embodiments, a semiconductor device includes: a plurality of first gate structures arranged along a first direction and extending in a second direction, at least one first gate structure of the plurality of first gate structures corresponding to a first transistor region; a plurality of second gate structures arranged along the first direction and aligned with ones of the first gate structures in the second direction, at least one second gate structure of the plurality of second gate structures corresponding to a second transistor region; an insulating structure extending in the second direction and separating the plurality of first gate structures from the plurality of second gate structures; and a first conductive via in the insulating structure and configured to carry a signal for the first transistor region.

In some embodiments, the first conductive via at least partially overlaps the at least one first gate structure and the at least one second gate structure along the second direction. In some embodiments, the insulating structure is a gate-cutting structure. In some embodiments, the first transistor region is in a first cell in a first row, the second transistor region is in a second cell in a second row abutting the first row, and the insulating structure extends along a first row boundary that extends in the first direction and is common to the first and second rows. In some embodiments, the second cell includes a reserved zone adjacent to the first conductive via, the reserved zone being free of a conductive via. In some embodiments, the reserved zone has a dimension corresponding to a dimension of the first conductive via. In some embodiments, the semiconductor device further includes a backside power rail in a layer below the insulating structure, the backside power rail being free of overlap with the first row boundary. In some embodiments, the first conductive via at least partially overlaps a backside power rail configured to provide a power voltage to the first transistor region.

In some embodiments, a method of fabricating a semiconductor device includes: forming initial gate structures arranged along a first direction and extending in a second direction, the initial gate structures corresponding to a first transistor region and a second transistor region that abut in the second direction; forming an insulating structure through the initial gate structures to divide the initial gate structures into first gate structures in the first transistor region and second gate structures in the second transistor region; and forming a first conductive via in the insulating structure, the first conductive via being configured to carry a signal for the first transistor region.

In some embodiments, the first conductive via is formed to at least partially overlap the a first one of the first gate structures and a first one of the second gate structures along the second direction. In some embodiments, forming the insulating structure includes: forming a trench that divides the initial gate structures into first gate structures in the first transistor region and second gate structures in the second transistor region, forming an insulating layer on sidewalls of the trench, and forming the first conductive via in a region of the trench where the initial gate structures were removed between the first gate structures and the second gate structures. In some embodiments, the first transistor region is formed in a first cell in a first row, the second transistor region is formed in a second cell in a second row abutting the first row, and the insulating structure is formed to extend along a first row boundary that extends in the first direction and is common to the first and second rows. In some embodiments, the method further includes forming a second conductive via in the second cell, the second conductive via being formed outside of a reserved zone in the second cell and adjacent to the first conductive via, such that the reserved zone is free of a conductive via. In some embodiments, the method further includes defining the reserved zone to have a dimension corresponding to a dimension of the first conductive via. In some embodiments, the method further includes forming a backside power rail in a layer below the insulating structure, the backside power rail being formed to be free of overlap with the first row boundary. In some embodiments, the conductive via is formed to at least partially overlap a backside power rail configured to provide a power voltage to the first transistor region.

In some embodiments, a semiconductor device includes: an upper transistor; a lower transistor under the upper transistor; an insulating structure extending in a first direction along a first cell boundary that separates a first cell, which includes the upper transistor and the lower transistor, from a second cell; a first backside power rail configured to provide a first power voltage; a second backside power rail configured to provide a second power voltage different from the first power voltage, the second backside power rail crossing inside the first cell and being spaced apart from the first cell boundary; a lower contact providing an electrical connection to the lower transistor; an upper contact providing an electrical connection to the upper transistor; a first conductive via configured to couple the first power voltage to the upper contact; and a second conductive via vertically overlapping the lower contact and being configured to couple a signal to the lower contact.

In some embodiments, the first backside power rail is in a first layer under the lower transistor and overlaps a first cell boundary of a cell that includes the upper and lower transistors, and the second backside power rail is in the first layer. In some embodiments, the first conductive via has a first height that extends at least from a bottom of a bottom active region of the lower transistor to a top of a top active region of the upper transistor, and the second conductive via has a second height corresponding to the first height. In some embodiments, the upper transistor and the lower transistor form a complementary field effect transistor.

In some embodiments, an insulating gate-cutting structure abuts a plurality of first gate structures and abuts a plurality of second gate structures. In some embodiments, a conductive signal via in an insulating gate-cutting structure has a height in a vertical direction normal to a substrate that is at least as great as a height of a CFET gate structure in the vertical direction.

In some embodiments, an integrated circuit includes a first standard cell and a second standard cell. The first standard cell includes a signal line in a front side of the first standard cell; a metal-to-device contact in a backside of the first standard cell; a cutting structure adjacent to a common boundary of the first standard cell and the second standard cell; and a first via that is in the cutting structure and is coupled between the signal line and the metal-to-device contact. The second standard cell abuts the cutting structure and includes a via-forbidden region adjacent to the first via.

In some embodiments, a method of fabricating a semiconductor device includes forming a plurality of gate structures spaced apart in a first direction and extending in a second direction; forming a cut pattern, the forming a cut pattern including: removing a portion of the gate structures along the first direction so as to section each gate structure of the plurality of gate structures into first and second gate segments, the first gate segments corresponding to a first cell and the second gate segments corresponding to a second cell that is adjacent to the first cell in the second direction; forming an insulating layer on surfaces exposed by the cut pattern, the forming an insulating layer including: forming an insulating structure that is interposed between facing ends of the first and second gate segments so as to isolate the first gate segments from the second gate segments, and allowing a portion of the cut pattern to remain as an opening in the insulating structure between facing ends of at least some of the first and second gate segments; and forming a conductive via in the opening such that the conductive via is surrounded by the insulating structure, the conductive via being configured to carry a signal for the first cell.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a plurality of first gate structures arranged along a first direction and extending in a second direction, at least one first gate structure of the plurality of first gate structures corresponding to a first transistor region;
a plurality of second gate structures arranged along the first direction and aligned with ones of the first gate structures in the second direction, at least one second gate structure of the plurality of second gate structures corresponding to a second transistor region;
an insulating structure extending in the second direction and separating the plurality of first gate structures from the plurality of second gate structures; and
a first conductive via in the insulating structure and configured to carry a signal for the first transistor region.

2. The semiconductor device of claim 1, wherein:
the first conductive via at least partially overlaps the at least one first gate structure and the at least one second gate structure along the second direction.

3. The semiconductor device of claim 1, wherein:
the insulating structure is a gate-cutting structure.

4. The semiconductor device of claim 1, wherein:
the first transistor region is in a first cell in a first row,
the second transistor region is in a second cell in a second row abutting the first row, and
the insulating structure extends along a first row boundary that extends in the first direction and is common to the first and second rows.

5. The semiconductor device of claim 4, wherein:
the second cell includes a reserved zone adjacent to the first conductive via, the reserved zone being free of a conductive via.

6. The semiconductor device of claim 5, wherein:
the reserved zone has a dimension corresponding to a dimension of the first conductive via.

7. The semiconductor device of claim 5, further comprising:
a backside power rail in a layer below the insulating structure, the backside power rail being free of overlap with the first row boundary.

8. The semiconductor device of claim 1, wherein:
the first conductive via at least partially overlaps a backside power rail configured to provide a power voltage to the first transistor region.

9. A method of fabricating a semiconductor device, the method comprising:
forming initial gate structures arranged along a first direction and extending in a second direction, the initial gate structures corresponding to a first transistor region and a second transistor region that abut in the second direction;
forming an insulating structure through the initial gate structures to divide the initial gate structures into first gate structures in the first transistor region and second gate structures in the second transistor region; and
forming a first conductive via in the insulating structure, the first conductive via being configured to carry a signal for the first transistor region.

10. The method of claim 9, wherein:
the first conductive via is formed to at least partially overlap the a first one of the first gate structures and a first one of the second gate structures along the second direction.

11. The method of claim 9, wherein:
forming the insulating structure includes:
forming a trench that divides the initial gate structures into first gate structures in the first transistor region and second gate structures in the second transistor region,
forming an insulating layer on sidewalls of the trench, and
forming the first conductive via in a region of the trench where the initial gate structures were removed between the first gate structures and the second gate structures.

12. The method of claim 9, wherein:
the first transistor region is formed in a first cell in a first row,
the second transistor region is formed in a second cell in a second row abutting the first row, and
the insulating structure is formed to extend along a first row boundary that extends in the first direction and is common to the first and second rows.

13. The method of claim 12, further comprising:
forming a second conductive via in the second cell, the second conductive via being formed outside of a reserved zone in the second cell and adjacent to the first conductive via, such that the reserved zone is free of a conductive via.

14. The method of claim 13, further comprising:
defining the reserved zone to have a dimension corresponding to a dimension of the first conductive via.

15. The method of claim 12, further comprising:
forming a backside power rail in a layer below the insulating structure, the backside power rail being formed to be free of overlap with the first row boundary.

16. The method of claim 9, wherein:
the conductive via is formed to at least partially overlap a backside power rail configured to provide a power voltage to the first transistor region.

17. A semiconductor device comprising:
an upper transistor;
a lower transistor under the upper transistor;
an insulating structure extending in a first direction along a first cell boundary that separates a first cell, which includes the upper transistor and the lower transistor, from a second cell;
a first backside power rail configured to provide a first power voltage;
a second backside power rail configured to provide a second power voltage different from the first power voltage, the second backside power rail crossing inside the first cell and being spaced apart from the first cell boundary;
a lower contact providing an electrical connection to the lower transistor;
an upper contact providing an electrical connection to the upper transistor;
a first conductive via configured to couple the first power voltage to the upper contact; and
a second conductive via vertically overlapping the lower contact and being configured to couple a signal to the lower contact.

18. The semiconductor device of claim 17, wherein:
the first backside power rail is in a first layer under the lower transistor and overlaps a first cell boundary of a cell that includes the upper and lower transistors, and
the second backside power rail is in the first layer.

19. The semiconductor device of claim 17, wherein:
the first conductive via has a first height that extends at least from a bottom of a bottom active region of the lower transistor to a top of a top active region of the upper transistor, and
the second conductive via has a second height corresponding to the first height.

20. The semiconductor device of claim 17, wherein:
the upper transistor and the lower transistor form a complementary field effect transistor.
